(19) United States
(12) Patent Application Publication
(10) Pub. No.: US 2026/0284702 A1
(43) Pub. Date: Sep. 24, 2026

(54) COATED STRUCTURED SUBSTRATES AND METHODS OF MAKING SAME

(71) Applicant: 3M INNOVATIVE PROPERTIES COMPANY, St. Paul, MN (US)

(72) Inventors: Brylee David B. Tiu, Falcon Heights, MN (US); Karl K. Stensvad, Eagan, MN (US); Caleb T. Nelson, McKinney, TX (US); Brandon R. Pietz, St. Paul, MN (US); Cedric Bedoya, Woodbury, MN (US); Jeffrey L. Solomon, Centerville, MN (US); Daniel J. Schmidt, Woodbury, MN (US); David J. Tarnowski, Mahtomedi, MN (US)

(21) Appl. No.: 19/479,482

(22) PCT Filed: May 20, 2024
(86) PCT No.: PCT/IB2024/054902

§ 371 Date: Oct. 28, 2025

Related U.S. Application Data
(60) Provisional application No. 63/511,399, filed on Jun. 30, 2023.

(51) Int. Cl. B05D 5/06; B05D 7/00; C23C 16/40; C23C 16/455; C23C 16/56; G02B 1/10; G02B 5/30

(52) U.S. Cl. CPC B05D 5/066; B05D 7/56; C23C 16/402; C23C 16/45551; C23C 16/56; G02B 1/10; G02B 5/3008; B05D 2203/30; B05D 2508/00; B05D 2601/22; G02B 2207/101

(57) ABSTRACT

The present disclosure provides a coated structured article. The article includes a substrate with a structured major surface including features, in which the structured major surface includes protruding features and/or recessed features. The article also includes a coating disposed on at least a portion of the features, the coating including a first material and a second material. The first material has a first binding group and the second material has a second binding group, and the first binding group and the second binding group have complementary interactions. A method of making the article is also provided. The method includes depositing layers using layer-by-layer self-assembly to form a coating on a structured substrate.

### BACKGROUND

Various structured substrates are known, having engineered structured shapes. Further developments in articles having structured surfaces would be desirable.

### SUMMARY

In a first aspect, an article is provided. The article comprises a substrate comprising a structured major surface comprising features, wherein the structured major surface comprises protruding features, recessed features, or a combination thereof. The article also comprises a coating disposed on at least a portion of the features, the coating comprising a first material and a second material. The first material comprises a first binding group and the second material comprises a second binding group, and the first binding group and the second binding group have complementary interactions.

In a second aspect a method of making an article is provided. The method comprises obtaining a substrate comprising a structured major surface comprising features, wherein the structured major surface comprises protruding features, recessed features, or a combination thereof. The method further comprises disposing onto the structured major surface a plurality of layers deposited by layer-by-layer self-assembly, thereby forming a coating disposed on at least a portion of the features. The coating comprises a first material and a second material. The first material comprises a first binding group and the second material comprises a second binding group, and the first binding group and the second binding group have complementary interactions.

Infrared (IR) metasurfaces are planar devices composed of subwavelength structures (i.e., meta-atoms) and can steer the polarization, phase, and amplitude of electromagnetic waves at the wavelengths between 0.700 micrometers and 300 micrometers. Their ability to control the properties of electromagnetic waves, particularly polarization, in the longer IR wavelength region allows these materials to play an important role for various applications including optical sensing, thermal imaging, and free-space wireless communication.

Fabricating metasurfaces based on silicon is widely known since silicon-based processes are common and readily available for wafer-based processes (e.g., up to 300 mm in diameter). However, many possible use cases require large part sizes, flexible substrates, or extremely high part volumes. In those cases, processing on flexible films would likely be preferrable if equivalent capabilities existed. There are distinct challenges when trying to transfer silicon metasurface processes to roll-to-roll (R2R) formats. For instance, the high temperatures required for deposition and etching would be damaging to most polymeric film substrates; IR wavelength functions require larger features when compared to visible wavelength metasurfaces, resulting in longer deposition times to generate thicker layers and increasing heat to the substrate; thick inorganic layers can be fragile yet highly stressed on flexible films, which can lead to web-handing challenges as well as fracturing or poor adhesion of the deposited layers; and materials to be used in the final construction must have appropriate optical properties in the desired IR wavelength region.

Articles according to the present disclosure are formed using layer-by-layer assembly of a coating on a structured substrate, which can be coated using a R2R format at temperatures of 100° C. or less.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples may be used in various combinations. In each instance, the recited list serves only as a representative group and should not be interpreted as an exclusive list.

### BRIEF DESCRIPTION OF THE DRAWINGS

FIG. 1 is a flow chart of an exemplary method according to the present disclosure.

FIG. 2 is a scanning electron microscopy (SEM) image of a cross-section of a portion of an exemplary article according to the present disclosure.

FIG. 3 is an SEM image of a cross-section of a portion of another exemplary article according to the present disclosure.

FIG. 4 is a schematic cross-sectional view of a stack of bi-layers.

FIG. 5 is a schematic cross-sectional of a portion of a further exemplary article according to the present disclosure.

FIG. 6A is an SEM image of a cross-section of a portion of a structured substrate.

FIG. 6B is an SEM image of a cross-section of a portion of an exemplary article according to the present disclosure, including a coating on the substrate of FIG. 6A.

FIG. 7 is an SEM image of a cross-section of a portion of an exemplary coating according to the present disclosure.

FIG. 8 is an SEM image of a cross-section of a portion of another exemplary coating according to the present disclosure.

FIG. 9 is an SEM image of a cross-section of a portion of a further exemplary coating according to the present disclosure.

FIG. 10A is a schematic cross-sectional view of a structured substrate that has a two-dimensional array of projections.

FIG. 10B is a top plan view of four representative engineered patterned regions for a two-dimensional array of projections.

FIG. 11A is a schematic cross-sectional view of a structured substrate having a plurality of cavities extending between two major surfaces.

FIG. 11B is generalized schematic exploded view of a structured substrate having a plurality of cavities extending between two major surfaces.

While the above-identified figures set forth various embodiments of the disclosure, other embodiments are also contemplated, as noted in the description. In all cases, this disclosure presents the invention by way of representation and not limitation. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

### Glossary

As used herein, “metasurface” refers to a two-dimensional subwavelength spacing or array of photonic resonators or truncated waveguides, which perform one or more optical functions. Each array locally acts on one or more physical properties of light, specifically, amplitude, phase, or polarization.

As used herein, “microstructures” refer to engineered elements having at least two feature dimensions that are microscopic, namely 1 micrometer to less than 1000 micrometers.

As used herein, “nanostructures” refers to engineered elements having at least one dimension that is less than 1 micrometer.

As used herein, “engineered” with respect to structures refers to surface features that were created from a specific design with deterministic position, size, shape, spacing, and dimensions.

As used herein, “aspect ratio” refers to the ratio of feature height to minimum feature width.

As used herein, “flexible polymeric film” refers to a polymeric film that may be elastically curved to a radius of curvatures of 52 mm or less.

As used herein, “operative phase profile” refers to the phase profile that is imparted by the metasurface on the incident electromagnetic radiation. It is designed to carry out specific optical functions.

As used herein, “land region thickness” refers to the height of a structured surface layer between its bottom surface and the plane defined by the bottom of the surface features. Also referred to as the residual layer or region.

As used herein, “bi-layer” or “bilayer” refer to a thin film comprising a first layer of a first material and a second layer of a second material. As described herein, in some embodiments the first layer is adjacent and in contact with the second layer. In some embodiments, the first layer is in substantially uninterrupted contact with the second layer.

As used herein, “in planar contact” or “planarly contacting” indicates that one layer or layered structure is contacting (and disposed either above or below) another layer or layered structure. Such contact is facial contact, rather than edge contact.

As used herein, “index of refraction”, also referred to as “index” or “RI”, refers to a refractive index of a material in the plane of the material with respect to light at 633 nm and normal or near normal (i.e., up to 8 degrees) incidence, unless otherwise indicated.

As used herein, “high refractive index” and “low refractive index” are relative terms and used when two layers are compared in both in-plane directions of interest. The layer that has greater in-plane average refractive index is the high refractive index layer, whereas the layer that has lower in-plane average refractive index is the low refractive index layer.

As used herein, “substantially planar” with respect to a coating layer means that a surface of the coating layer is essentially free of roughness extending above and/or below a plane of the layer of under 1 micrometer, such as under 500 nanometers (nm), under 100 un, or under 50 nm. The roughness present on a coating layer surface can be measured with a confocal microscope or atomic force microscope, for example.

As used herein, the term “essentially free” in the context of a composition being essentially free of a component, refers to a composition containing less than 1% by weight (wt. %), 0.5 wt. % or less, 0.25 wt. %, 0.1 wt. %, 0.05 wt. %, 0.001 wt. %, or 0.0001 wt. % or less of the component, based on the total weight of the composition; or less than 1% by volume (vol. %), 0.5 vol. % or less, 0.25 vol. %, 0.1 vol. %, 0.05 vol. %, 0.001 vol. %, or 0.0001 vol. % or less of the component, based on the total volume of the composition.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

In this application, terms such as “a”, “an”, and “the” are not intended to refer to only a singular entity, but include the general class of which a specific example may be used for illustration. The terms “a”, “an”, and “the” are used interchangeably with the term “at least one.” The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise.

The term “and/or” means one or all of the listed elements or a combination of any two or more of the listed elements.

Also herein, all numbers are assumed to be modified by the term “about” and preferably by the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used. Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

As used herein as a modifier to a property or attribute, the term “generally”, unless otherwise specifically defined, means that the property or attribute would be readily recognizable by a person of ordinary skill but without requiring absolute precision or a perfect match (e.g., within +/−20% for quantifiable properties). The term “substantially”, unless otherwise specifically defined, means to a high degree of approximation (e.g., within +/−10% for quantifiable properties) but again without requiring absolute precision or a perfect match. Terms such as same, equal, uniform, constant, strictly, and the like, are understood to be within the usual tolerances or measuring error applicable to the particular circumstance rather than requiring absolute precision or a perfect match.

In a first aspect, an article is provided. The article comprises:
a substrate comprising a structured major surface comprising features, wherein the structured major surface comprises protruding features, recessed features, or a combination thereof; and
a coating disposed on at least a portion of the features, the coating comprising a first material and a second material, wherein the first material comprises a first binding group and the second material comprises a second binding group, and wherein the first binding group and the second binding group have complementary interactions.

In a second aspect, a method of making an article is provided. The method comprises:
obtaining a substrate comprising a structured major surface comprising features, wherein the structured major surface comprises protruding features, recessed features, or a combination thereof; and
disposing onto the structured major surface a plurality of layers deposited by layer-by-layer self-assembly, thereby forming a coating disposed on at least a portion of the features, the coating comprising a first material and a second material, wherein the first material comprises a first binding group and the second material comprises a second binding group, and wherein the first binding group and the second binding group have complementary interactions.

The first and second aspects are described in detail below.

Referring to FIG. 1, methods according to the present disclosure include Step 110 to obtain a substrate comprising a structured major surface comprising features, wherein the structured major surface comprises protruding features, recessed features, or a combination thereof. Methods further include Step 120 to dispose onto the structured major surface a plurality of layers deposited by layer-by-layer self-assembly, thereby forming a coating disposed on at least a portion of the features, the coating comprising a first material and a second material, wherein the first material comprises a first binding group and the second material comprises a second binding group, and wherein the first binding group and the second binding group have complementary interactions.

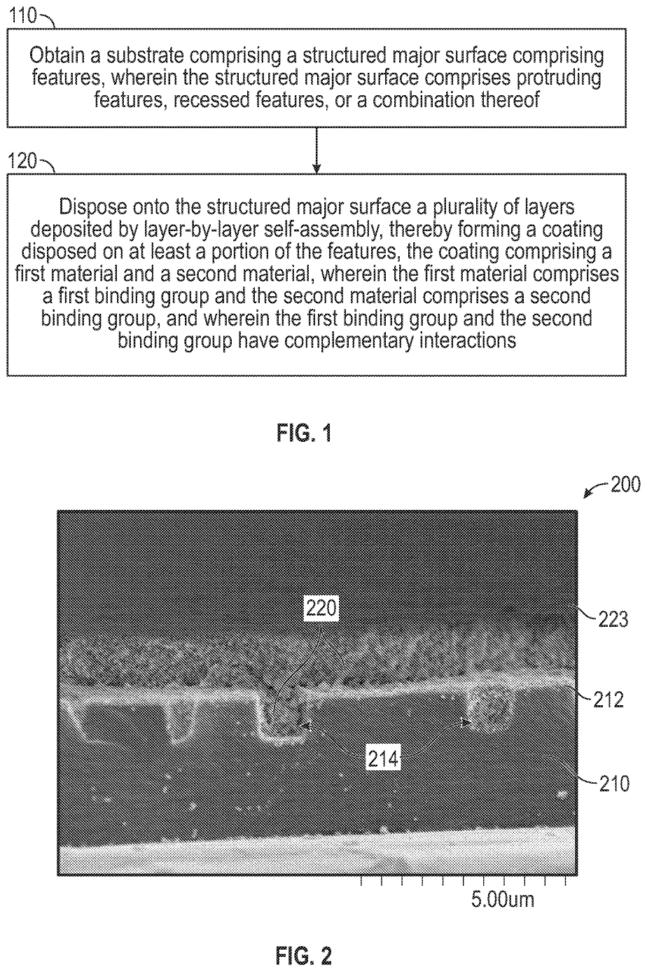

Referring to FIG. 2, a scanning electron microscopy (SEM) image is provided of a cross-section of a portion of an exemplary article 200. The article 200 comprises a substrate 210 comprising a structured major surface 212 comprising recessed features 214; and a coating 220 disposed on at least a portion of the features 214. In some articles 200 according to the present disclosure, the coating 220 has a major surface 223, opposite the substrate 210, that is substantially planarized.

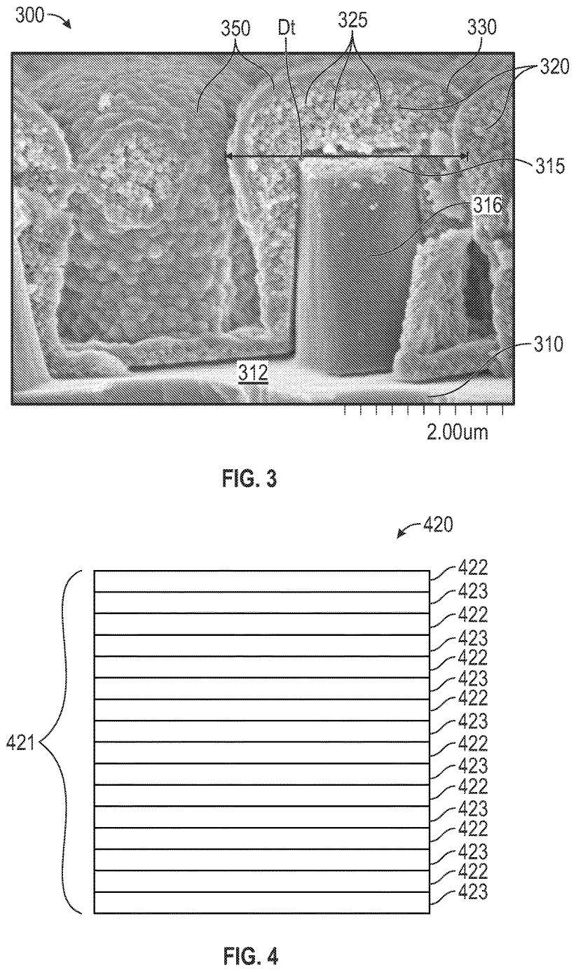

Referring to FIG. 3, an SEM image is provided of a cross-section of a portion of an exemplary article 300. The article 300 comprises a substrate 310 comprising a structured major surface 312 comprising protruding features 316; and a coating 320 disposed on at least a portion of the features 316.

Referring to FIG. 4, the coating 420 (e.g., 220 in FIGS. 2 and 320 in FIG. 3) comprises a first material 422 and a second material 423, wherein the first material 422 comprises a first binding group and the second material 423 comprises a second binding group, and wherein the first binding group and the second binding group have complementary interactions.

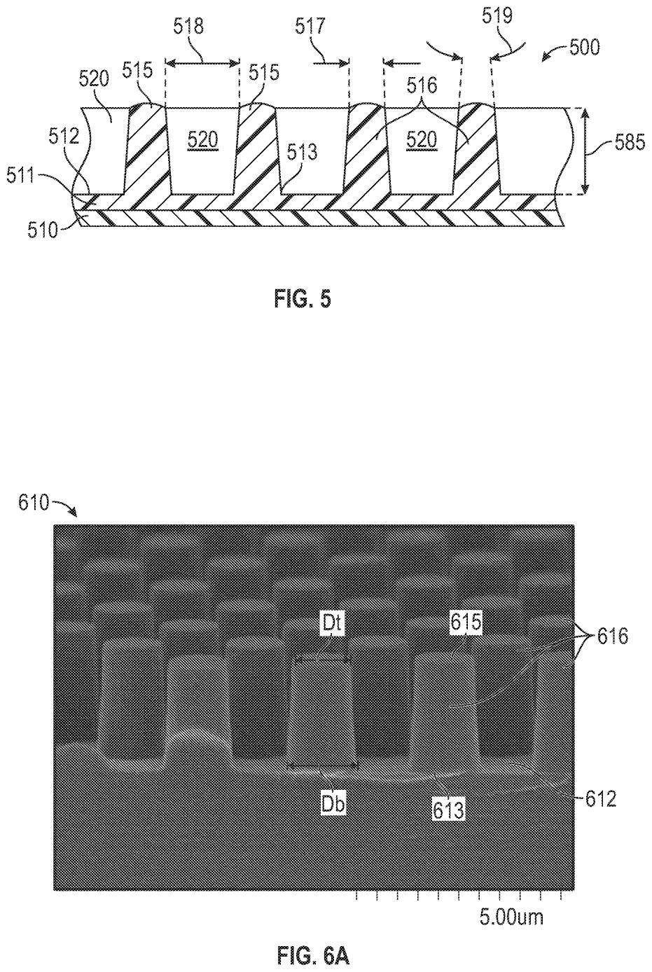

Referring to FIG. 5, in certain embodiments, an article 500 is provided in which the features 516 of a structured substrate 510 comprise a top surface 515 opposite the substrate 510 and wherein the top surface 515 of at least a portion of the features 516 lacks the coating 520 disposed thereon. Rather, the coating 520 tends to be disposed between features 516.

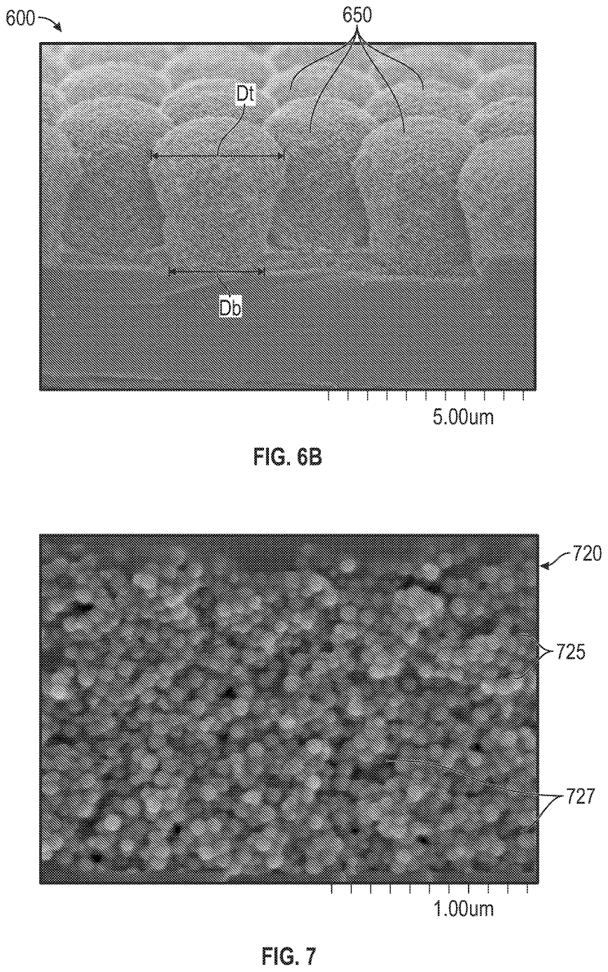

Referring to FIG. 6A, an SEM image is provided of a cross-section of a portion of a substrate 610 comprising a structured major surface 612 comprising protruding features 616. It is noted that in the substrate 610 of FIG. 6A, the structured major surface comprises a plurality of protruding features each comprising a base 613 extending from the major surface 612 and a top 615 distal to the major surface 612, wherein a diameter Db at the base 613 is equal to or greater than a dimeter Dt at the top 615. As described in detail in Example 8, the substrate 610 of FIG. 6A was coated according to the present disclosure and FIG. 6B shows that the overall shape of the coated features 650 is opposite of the overall shape of the uncoated features 616 of FIG. 6A. Unexpectedly, it was discovered that in some cases, when a coating is applied to such a substrate 610, as can be seen in FIG. 6B, the resulting article 600 comprises a plurality of coated features 650 that each has a diameter Dt at a top 615 of the feature 616 that is greater than a diameter Db of a base 653. By “diameter” is meant the longest distance that passes through a center of the feature or the coated feature. The cross-sectional view in FIG. 3 confirms the location of the top 315 of the feature 316 in the coated feature 350 at the diameter Dt.

In some embodiments, the coating and the features have different refractive indices from each other. For instance, a difference in refractive index of the coating from the refractive index of the features (e.g., ΔRI) may be at least 0.2, 0.25, 0.3, 0.35, 0.4, 0.45, 0.5, 0.55, 0.6, 0.65, 0.7, or at least 0.75. The difference in refractive index between the coating and the features is optionally as high as 2.35, 2.3, 2.25, 2.2, 2.15, 2.1, 2.05, 2.0, 1.95, 1.9, 1.85, 1.8, 1.75, 1.7, 1.65, 1.6, 1.55, 1.5, 1.45, 1.4, 1.35, 1.3, 1.25, 1.2, 1.15, 1.0, 1.05, 1, 0.95, 0.9, 0.85, or as high as 0.8. In some cases, the coating is a low refractive index material while the features are the high refractive index material. In select embodiments, the coating exhibits a refractive index of 1.25 or greater, 1.3, 1.35, 1.4, or 1.45 or greater, and 1.6 or less, 1.55, 1.5, or 1.45 or less. For example, the coating optionally exhibits a refractive index of 1.25 to 1.45. In some cases, the coating is a high refractive index material while the features are the low refractive index material.

The coating (e.g., layer) on the structured major surface comprises one or more polyions. The coating is typically deposited by the layer-by-layer (LbL) assembly process. This process is commonly used to assemble films or coatings of oppositely charged polyions electrostatically, but other functionalities such as hydrogen bond donor/acceptors, metal ions/ligands, and covalent bonding moieties can be the driving force for film assembly. Polymers, nanoparticles, and small molecules can be referred to as “polyionic” or “polyion” or, specifically, “polyanionic”, “polyanion”, “polycation” or “polycationic,” if they contain a plurality of negative or positive ionic charged sites, respectively. Examples of polyelectrolytes and nanoparticles are described in greater detail below. “Polyelectrolyte” means a polymer or compound with multiple ionic groups (i.e., “binding groups”) capable of electrostatic interaction, e.g., cationic functional groups and/or anionic functional groups. The complementary interactions between the first binding group and the second binding group of the first and second materials, respectively, are usually complementary electrostatic interactions or complementary hydrogen bonding interactions between hydrogen bond donors and hydrogen bond acceptors.

Typically, an LbL deposition process involves exposing the substrate (e.g., a microstructured film) having a surface charge, to a series of liquid solutions, or baths. This can be accomplished by immersion of the substrate into liquid baths (also referred to as dip coating), spraying, spin coating, roll coating, inkjet printing, and the like. Exposure to the first polyion (e.g., polyelectrolyte bath) liquid solution, which has charge opposite that of the substrate, results in charged species near the substrate surface adsorbing quickly, establishing a concentration gradient, and drawing more polyelectrolyte from the bulk solution to the surface. Further adsorption occurs until a sufficient layer has developed to mask the underlying charge and reverse the net charge of the substrate surface. In order for mass transfer and adsorption to occur, this exposure time is typically on the order of seconds to minutes. The substrate is then removed from the first polyion (e.g., bath) liquid solution, and is then exposed to a series of water rinse baths to remove any physically entangled or loosely bound polyelectrolyte. Following these rinse (e.g., bath) liquid solutions, the substrate is then exposed to a second polyion liquid solution, which has charge opposite that of the first polyion (e.g., bath) liquid solution. Once again adsorption occurs, since the surface charge of the substrate is opposite that of the second (e.g., bath) liquid solution. Continued exposure to the second polyion (e.g., bath) liquid solution then results in a reversal of the surface charge of the substrate. A subsequent rinsing can be performed to complete the cycle. This sequence of steps is said to build up one layer pair, also referred to herein as a “bi-layer” of deposition and can be repeated as desired to add further layer pairs to the substrate. In one embodiment, the plurality of layers deposited by layer-by-layer assembly is a polyelectrolyte stack comprising an organic polymeric polyion (e.g., cation) and an organic polymeric counterion (e.g., anion). Optionally, a single monolayer of a charged material, i.e., one half bi-layer, may be employed as the coating on the microstructures. A monolayer may typically have an average thickness in the range of 0.1 nm to 5 nm for soluble polymers and 5 nm to 100 nm for polymer dispersions.

Some examples of suitable processes include those described in Krogman et al., U.S. Pat. No. 8,234,998; Hammond-Cunningham et al., US2011/0064936; and Nogueira et al., U.S. Pat. No. 8,313,798. Layer-by layer dip coating can be conducted using a StratoSequence VI (nanoStrata Inc., Tallahassee, FL) dip coating robot or using an automated deposition system as described in Gamboa et al. (Rev. Sci. Instrum. 81, 036104 (2010)).

From a practical perspective, it is possible that not every LbL process will result in 100% of the features of the structured substrate having a layer of coating disposed on their surfaces. At least 10% of the features comprise the coating, 15% or greater, 20%, 25%, 30%, 35%, 40%, 45%, 50%, 55%, 60%, 65%, 70%, 75%, 80%, 82%, 84%, 86%, 88%, 90%, 92%, 94%, 96% or 98% or greater of the features comprise the coating.

In some embodiments, each of the first material and the second material comprises nanoparticles. In such a case, one set of polyionic nanoparticles comprise polycations while the other set of polyionic nanoparticles comprise polyanions. In other embodiments, the first material comprises nanoparticles and the second material comprises a polyelectrolyte. In some embodiments, the first material comprises a polyanion and the second material comprises a polycation, whereas in other embodiments the first material comprises a polycation and the second material comprises a polyanion. In some embodiments, a polyelectrolyte is a polycation while in other embodiments, a polyelectrolyte is a polyanion. The material that comprises a polycation typically contacts the structured major surface of the substrate.

Referring back to FIGS. 2 and 3, in some cases, the coating 220, 320 comprises a three-dimensional porous matrix in which the first material comprises nanoparticles (e.g., SiO₂). In particular, numerous nanoparticles 325 are readily visible in the three-dimensional porous matrix of the coating 320. Also in the embodiments shown in FIGS. 2 and 3, the second material comprises nanoparticles. Further details are provided in Examples 9 and 14, below. In select embodiments, the coating of an article consists essentially of a three-dimensional porous matrix. By “consists essentially of a three-dimensional porous matrix” is meant as excluding anything other than additives and/or impurities contained in dispersions used to form the coating. Contents of suitable dispersions are described in detail below.

A plurality of layers deposited by layer-by-layer self-assembly is disposed upon a major surface of a structured substrate. The plurality of layers deposited by layer-by-layer self-assembly comprises at least two layers applied by what is commonly referred to as a “layer-by-layer self-assembly process”. This process is commonly used to assemble films or coatings of oppositely charged polyelectrolytes electrostatically, but other functionalities such as hydrogen bond donor/acceptors, metal ions/ligands, and covalent bonding moieties can be the driving force for film assembly.

In some embodiments, the thickness of a bi-layer, the number of bi-layers per stack, the number of stacks, and the thickness of each stack are selected to achieve the desired optical properties using the minimum total thickness of self-assembled layers and/or the minimum number of layer-by-layer deposition steps. In such embodiments, the thickness of each bi-layer typically ranges from about 1 nm to 100 nm. In such embodiments, the number of bi-layers per stack typically ranges from about 1 to 200. In such embodiments, the number of stacks is typically 1, 2, 3, or 4 and no greater than 20, 19, 18, 17, or 15. In such embodiments, the thickness of a stack is typically at least 25 mu, 35 nm, 45 nm, 55 nm, 65 nm, 75 nm, or 85 nm and no greater than 3000 nm, 2500 nm, 2000 nm, 1500 nm, 1000 nm, 500 nm, 250 nm, 200 nm, or 150 nm. In other embodiments, the number of bi-layers is selected to achieve the desired transmission in combination with mechanical durability. In this embodiment, the thickness of a bi-layer and number of bi-layers may approach the maximum values. Further, this embodiment may utilize a single stack of low or high refractive index that may be selected to have a contrasting refractive index to the structured substrate to which it is applied. For example, referring again to FIG. 4, a low refractive index stack 421 may comprise bi-layers of that comprise a layer 423 of low refractive index inorganic oxide nanoparticles, such as SiO₂, as a polyanion and a layer 422 of polycationic low refractive index inorganic oxide nanoparticles, such as alumina-coated SiO₂. In FIG. 4 the illustrative low refractive index stack 421 comprises 8 alternating bi-layers.

Suitable polycations may include inorganic nanoparticles (for example, silicon oxide, aluminum oxide, zirconium oxide, titanium dioxide, silicon) suitably below their native isoelectric point, or alternatively surface-modified with positively charged functional groups. Suitable anions may include inorganic nanoparticles (for example, silicon oxide, aluminum oxide, zirconium oxide, titanium dioxide, silicon, nano-clay) suitably above their native isoelectric point, or alternatively surface-modified with negatively charged functional groups.

Suitable inorganic nanoparticles typically have an average primary or agglomerate particle size diameter of at least 1, 2, 3, 4, or 5 nanometers and typically no greater than 80, 100, 120, 140, 160, 180, or 200 nanometers. The average particle size of the nanoparticles of the dried self-assembled layers can be measured using transmission electron microscopy or scanning electron microscopy, for example. The average particle size of the nanoparticles in the nanoparticle suspension can be measured using dynamic light scattering, for example. “Agglomerate” refers to a weak association between primary particles which may be held together by charge or polarity and can be broken down into smaller entities. “Primary particle size” refers to the mean diameter of a single (non-aggregate, non-agglomerate) particle. As used herein “aggregate” with respect to particles refers to strongly bonded or fused particles where the resulting external surface area may be significantly smaller than the sum of calculated surface areas of the individual components. The forces holding an aggregate together are strong forces, for example covalent bonds, or those resulting from sintering or complex physical entanglement. Although agglomerated nanoparticles can be broken down into smaller entities such as discrete primary particles such as by application of a surface treatment; the application of a surface treatment to an aggregate simply results in a surface treated aggregate.

In some embodiments the (e.g., silica) nanoparticles have a relatively small average particle size. For example, the average primary or agglomerate particle size may be less than 30 nm, or 25 nm, or 20 nm, or 15 nm.

In some embodiments, the nanoparticles of a low refractive index stack or layer-by-layer self-assembled coating have a refractive index of no greater than 1.50, such as silica. Nanoparticles for use in the low refractive index bi-layer or stack can include silica (although other oxides can be used, such as zirconia, alumina, ceria, tin (stannic) oxide,), or composite nanoparticles such as core-shell nanoparticles. A core-shell nanoparticle can include a core of an oxide (e.g., iron oxide) or metal (e.g., gold or silver) of one type and a shell of silica or another material deposited on the core. Herein, “silica nanoparticles” refer to nanoparticles that include only silica as well as core-shell nanoparticles with a surface that includes silica. It is appreciated however, that unmodified silica nanoparticles commonly comprise hydroxyl or silanol functional groups on the nanoparticle surface, particularly when the nanoparticles are provided in the form of an aqueous dispersion. Aqueous dispersions of silica nanoparticles can also be ammonium or sodium stabilized. Silica has an isoelectric point at about pH 2 and can thus be used as a polyanion in the layer-by-layer self-assembly process at pH values greater than 2, more preferably at pH values greater than or equal to 3.

Inorganic silica sols in aqueous media are well known in the art and available commercially. Silica sols in water or water-alcohol solutions are available commercially under such trade names as LUDOX (manufactured by E.I. duPont de Nemours and Co., Inc., Wilmington, DE), NYACOL (available from Nyacol Co., Ashland, MA) or NALCO (manufactured by Nalco Water, Naperville, IL). Some useful silica sols are NALCO 1115, 2326, 1050, 2327, and 2329 available as silica sols with mean particle sizes of 4 nanometers (nm) to 77 nm. Another useful silica sol is NALCO 1034a available as a silica sol with mean particle size of 20 nanometers. A useful silica sol is NALCO 2326 available as a silica sol with mean particle size of 5 nanometers. Additional examples of suitable colloidal silicas are described in U.S. Pat. No. 5,126,394 (Revis et al.).

Clay platelet nanoparticles, such as montmorillonite, bentonite, and hectorite nanoparticles may be used, particularly for embodiments wherein the self-assembled layers provide a durable top coating for the article. Clay platelet-containing layer-by-layer self-assembled coatings can also impart flame retardance, oxygen barrier, water barrier, and corrosion-resistance properties to a coated substrate.

In some embodiments, the nanoparticles of the layer-by-layer self-assembled high refractive index bi-layer, stack or self-assembled top coat have a refractive index of greater than 1.60, 1.65, 1.70, 1.75, 1.80, 1.85, 1.90, 1.95, 2.00, 2.05, 2.10, 2.15, 2.20, 2.25, 2.30, 2.35, 2.40, 2.45, 2.50, 2.55, 2.60 such as silicon, titania, zirconia, alumina, tin oxides, antimony oxides, ceria, zinc oxide, lanthanum oxide, tantalum oxide, mixed metal oxides thereof, and mixtures thereof. Zirconia sols are available from Nalco Water under the trade designation “NALCO 00SS008”, Buhler AG Uzwil, Switzerland under the trade designation “BUHLER zirconia Z-WO sol” and Nissan Chemical America Corporation under the trade name NanoUse ZR™. Zirconia nanoparticles can also be prepared such as described in U.S. Patent Publication No. 2006/0148950 (Davidson et al.) and U.S. Pat. No. 6,376,590 (Kolb et al.). A nanoparticle dispersion that comprises a mixture of tin oxide and zirconia covered by antimony oxide (RI~1.9) is commercially available from Nissan Chemical America Corporation under the trade designation “HX-05M5”. A tin oxide nanoparticle dispersion (RI~2.0) is commercially available from Nissan Chemicals Corp. under the trade designation “CX-S501M”.

In some embodiments, the layer-by-layer self-assembled bi-layer, stack, or coating comprises titania. Various forms of titania can be utilized including anatase, brookite, rutile and amorphous forms. Anatase titania nanoparticles (5-15 nm diameter) is commercially available from U.S. Research Nanomaterials, Houston, TX as an aqueous suspension at 15 wt. %. TiO₂ sols are also available dispersed in strong acid or base condition from Ishihara Sangyo Kaisha Ltd. Titania has an isoelectric point at about pH 4-6 and thus can be used as a polyanion in layer-by-layer self-assembly at pH greater than 6, preferably pH greater than 7, more preferably pH greater than 8, or the polycation in layer-by-layer self-assembly at pH less than 4, more preferably pH less than 3.

Various other organic and inorganic nanoparticle particles can be used for the low refractive index or high refractive index layer of the self-assembled layers, as known in the art, some of which are described in Kurt et al., US 2010/0290109.

Referring again to FIG. 4, in some cases, the coating 420 comprises a first material 422 comprising nanoparticles and a second material 423 comprising a polymeric polyelectrolyte.

Suitable polymers that include a plurality of positively charged ionic (or ionizable) groups (i.e., polycationic polymers) can be derived from the following monomers, for example:
Primary amino-containing monomers and their salts (e.g., hydrochloride salts): vinyl amine, allyl amine, aminoalkyl (meth)acrylamide, aminoalkyl (meth)acrylate, 2-N-morpholinoalkyl (meth)acrylate,
Secondary amino-containing monomers and their salts (e.g., hydrochloride salts): alkylaminoalkylene (meth)acrylates such as, for example, 2-(methylamino)ethyl (meth)acylate
Tertiary amino-containing monomers and their salts (e.g., hydrochloride salts): various N,N-dialkylaminoalkyl (meth)acrylates and N,N-dialkylaminoalkyl (meth)acrylamides such as N,N-dimethyl aminoethyl (meth)acrylate, N,N-dimethylaminoethyl (meth)acrylamide, N,N-dimethylaminopropyl (meth)acrylate, N,N-dimethylaminopropyl (meth)acrylamide, N,N-diethylaminoethyl (meth)acrylate, N,N-diethylaminoethyl (meth)acrylamide, N,N-diethylaminopropyl (meth)acrylate, and N,N-diethylaminopropyl (meth)acrylamide, (tert-butylamino)alkyl methacrylate, (tert-butylamino)alkyl methacrylamide;
Quaternary amino-containing monomers: methacryloylaminopropyl trimethylammonium chloride, diallyldimethylammonium chloride, 2-acryloxyalkyltrimethylammonium chloride.

Strong polyelectrolytes may be utilized when a polymer is included in the bi-layers. For example, poly(sodium 4-styrene sulfonate) (SPS) may be utilized as a negatively charged anionic layer while poly(diallyldimethylammonium chloride (PDAC) may be as a positively charged cationic layer.

Some of the more common polycationic polymers used for layer-by-layer coating are: linear and branched poly(ethylenimine) (PEI), poly(allylamine hydrochloride), polyvinylamine, chitosan, polyaniline, polyamidoamine, poly(vinylbenzyltrimethylamine), polydiallyldimethylammonium chloride (PDAC), poly(dimethylaminoethyl methacrylate), poly[(3-methacryloylamino)propyl]-trimethylammonium chloride, and combinations thereof including copolymers thereof.

Suitable polycations may also include polymer latexes, dispersions, or emulsions with positively charged functional groups on the surface. Examples include Sancure 20051 and Sancure 20072 cationic polyurethane dispersions available from Lubrizol Corporation (Wickliffe, OH).

Suitable polymers that include negatively charged ionic (or ionizable) groups (i.e., polyanionic polymers) can be derived from these monomers (and salts thereof), for example: Acid monomers: (meth)acrylic acid, ß-carboxyethyl (meth)acylate, 2-(meth)acryloyloxyethyl phthalic acid, 2-(meth)acryloyloxy succinic acid, vinyl phosphonic acid, vinyl sulfonic acid, styrene sulfonic acid, and 2-acrylamido-2-methylpropane sulfonic acid, (meth)acrylate salts (i.e., zinc acrylate, zirconium acrylate, etc.), carboxyethyl (meth)acrylate salts (i.e., zirconium carboxyethyl acrylate), 2-sulfoalkyl (meth)acrylate, phosphonoalkyl (meth)acrylate, phosphoric acid 2-hydroxyethyl methacrylate ester.

Some of the more common polyanionic polymers used for layer-by-layer coating are: poly(vinyl sulfate), poly(vinyl sulfonate), poly(acrylic acid) (PAA), poly(methacrylic acid), poly(styrene sulfonate), dextran sulfate, heparin, hyaluronic acid, carrageenan, carboxymethylcellulose, alginate, sulfonated tetrafluoroethylene based fluoropolymers such as Nafion®, poly(vinylphosphoric acid), poly(vinylphosphonic acid), and combinations thereof including copolymers thereof. In some embodiments, the polycation is selected from the group consisting of polydiallyldimethylammonium chloride, polyethylenimine, polyallylamine, poly(2-(trimethylamino)ethyl methacrylate, and copolymers thereof.

Suitable polyanions may also include polymer latexes, dispersions, or emulsions with negatively charged functional groups on the surface. Such polymers are available, for example, under the JONCRYL tradename (BASF, Florham Park, NJ), CARBOSET tradename (Lubrizol Corporation), and NEOCRYL tradename (Covestro Coating Resins, Wilmington, MA).

The molecular weight of the polyelectrolyte polymers can vary, typically ranging from about 1,000 g/mole to about 1,000,000 g/mole. In some embodiments, the weight average molecular weight (Mw) of a negatively charged anionic layer ranges from 50,000 g/mole to 150,000 g/mole. In some embodiments, the weight average molecular weight (Mw) of a positively charged cationic layer ranges from 50,000 g/mole to 300,000 g/mole or from 10,000 g/mole to 50,000 g/mole.

Typically, the polyelectrolyte is prepared and applied to the microstructured surface as an aqueous solution. The term “aqueous” means that the liquid of the coating contains at least 85 percent by weight of water. It may contain a higher amount of water such as, for example, at least 90, 95, or even at least 99 percent by weight of water or more. The aqueous liquid medium may comprise a mixture of water and one or more water-soluble organic cosolvent(s), in amounts such that the aqueous liquid medium forms a single phase. Examples of water-soluble organic cosolvents include methanol, ethanol, isopropanol, 2-methoxyethanol, 3-methoxypropanol, 1-methoxy-2-propanol, tetrahydrofuran, and ketone or ester solvents. The amount of organic cosolvent typically does not exceed 15 wt. % of the total liquids of the coating composition. When a polyelectrolyte is a polymer, the aqueous polyelectrolyte composition for use in layer-by-layer self-assembly typically comprises at least 0.01 wt. %, 0.05 wt. % or 0.1 wt. % of polyelectrolyte and typically no greater than 5 wt. %, 4 wt. %, 3 wt. %, 2 wt. % or 1 wt. %.

When the bi-layers include both inorganic nanoparticles and a polymer, the concentration of inorganic nanoparticles is typically at least 30 wt. % of the dried low refractive index stack, high refractive index stack, or totality of self-assembled polymer-nanoparticle layers. The concentration of inorganic nanoparticles is typically no greater than about 90, 95, or 99 wt. %. The concentration of inorganic nanoparticles can be determined by methods known in the art, such as thermogravimetric analysis. In some embodiments, the dried low refractive index stack, high refractive index stack, or totality of bi-layers comprises at least 50, 55, 60, 65, or 70 wt. % of inorganic nanoparticles to provide better mechanical durability and scratch resistance in addition to optical properties.

Alternatively, when the bi-layers include both inorganic nanoparticles and a polymer, the concentration of inorganic nanoparticles is typically at least 5 volume percent (vol. %) of the dried low refractive index stack, high refractive index stack, or totality of self-assembled polymer-nanoparticle layers, such as 10 vol. % or greater, 15 vol. %, 20 vol. %, 25 vol. %, 30 vol. %, 35 vol. %, 40 vol. %, 45 vol. %, 50 vol. %, 55 vol. %, 60 vol. %, 65 vol. %, 70 vol. %, or 75 vol. % or greater. The concentration of inorganic nanoparticles is typically no greater than about 95 vol. %, 95 vol. %, 85 vol. %, or no greater 80 vol. %. In some cases, when the bi-layers include oppositely charged, spherical inorganic nanoparticles of the same size, a suitable maximum inorganic content of the dried low refractive index stack, high refractive index stack, or totality of self-assembled polymer-nanoparticle layers, is about 74%. Greater vol. % values are possible, however, for particles of different size and/or non-spherical particles. The volume percent concentration of inorganic nanoparticles can be determined by methods known in the art, such as by electron microscopy, for example.

In some embodiments, the aqueous solutions further comprise a “screening agent”, an additive that promotes even and reproducible deposition by increasing ionic strength and reducing interparticle electrostatic repulsion. In the case of aqueous solutions comprising soluble polyelectrolytes, the screening agents can change the conformation of the polymer chains, thereby altering the thickness of the resulting coating as well as the degree of intrinsic versus extrinsic charge compensation. Intrinsic charge compensation occurs when a positively charged functional group on one material (e.g., polymer) is charge neutralized by a negatively charged functional group on another material (e.g., polymer). Extrinsic charge compensation occurs when a charged functional group on a material (e.g., polymer) is charge neutralized by a small counterion (e.g., a positively charged functional group neutralized by a chloride ion, or a negatively charged functional group neutralized by a sodium ion). Suitable screening agents include any low molecular weight salts such as halide salts, sulfate salts, nitrate salts, phosphate salts, fluorophosphate salts, and the like. Examples of halide salts include chloride salts such as LiCl, NaCl, KCl, CaCl₂, MgCl₂, NH₄Cl and the like, bromide salts such as LiBr, NaBr, KBr, CaBr₂, MgBr₂, and the like, iodide salts such as LiI, NaI, KI, CaI₂, MgI₂, and the like, and fluoride salts such as, NaF, KF, and the like. Examples of sulfate salts include Li₂SO₄, Na₂SO₄, K₂SO₄, (NH₄)₂SO₄, MgSO₄, CoSO₄, CuSO₄, ZnSO₄, SrSO₄, Al₂(SO₄)₃, and Fe₂(SO₄)₃. Organic salts such as (CH₃)₃CCl, (C₂H₅)₃CCl, and the like are also suitable screening agents. Suitable screening agent concentrations can vary with the ionic strength of the salt. In some embodiments, the aqueous solution comprises (e.g., NaCl) screening agent at a concentration ranging from 0.01 M to 2 M.

In some embodiments where the coating comprises a three-dimensional porous matrix, it may be beneficial to deposit a third material into a plurality of pores of the porous matrix, e.g., also referred to as “backfilling” pores of the porous matrix. Backfilling may be advantageous to assist in at least one benefit of increasing the mechanical strength of the coating or achieving a specific desired refractive index of the final coating by replacing empty pores with a suitable material. Referring to FIG. 7, an SEM image is provided of a cross-section of a portion of a coating 720 including a three-dimensional porous matrix of silica nanoparticles 725 that was filled with a third material 727 (i.e., polydimethylsiloxane), as described in detail below in Example 27. Optionally, the third material is deposited by applying a solution of the third material onto the coating. In some cases, it is advantageous to crosslink the third material, which tends to also contribute to increasing the mechanical strength of the coating. Crosslinking may be achieved as known to those of skill in the art, for instance using thermal curing, photoinitiation, and/or a crosslinking agent. In certain embodiments, particularly when silica nanoparticles are included in the coating, the third material comprises a silicon-containing material. Such a third material may comprise at least one of the following silicon-containing materials: polydimethylsiloxane, a polysilsesquioxane, a polysiloxane, a silicone, a silicone acrylate, a silicate, a polycarbosilane, a polysilazane, or a siloxane-organic copolymer.

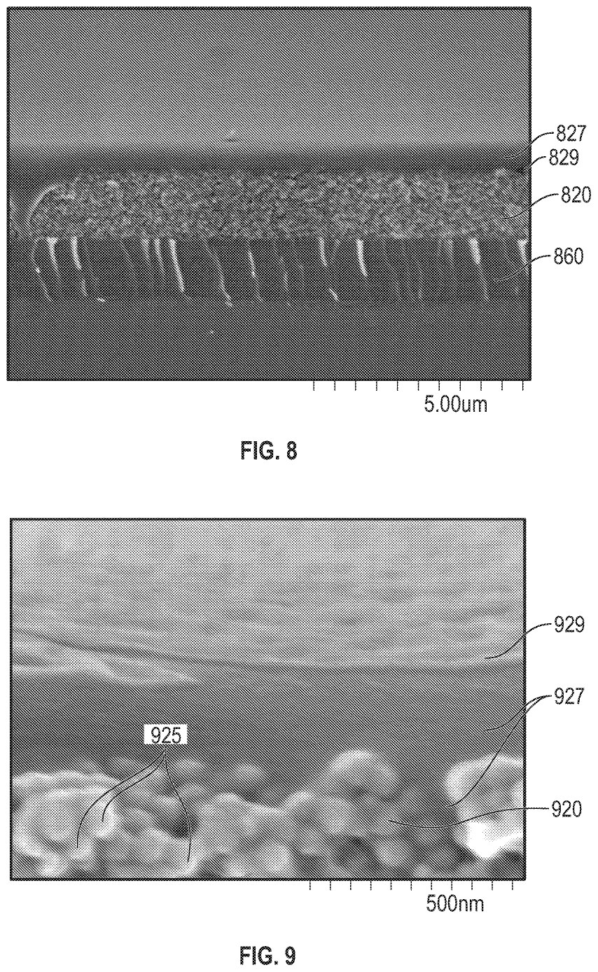

Depending on how much of the third material is added, the resulting coating will include a portion of the pores of the three-dimensional porous matrix being filled by the third material, all of the pores of the three-dimensional porous matrix being filled by the third material, or both all of the pores of the three-dimensional porous matrix being filled by the third material and an additional (discontinuous or continuous) coating of the third material on top of the porous matrix. Referring to FIG. 8, an SEM image is provided of a cross-section of a portion of a coating 820 deposited on a silicon wafer 860. The coating 820 includes a three-dimensional porous matrix of silica nanoparticles that was filled with a third material (i.e., polydimethylsiloxane (PDMS)), as described in detail below in Example 27. Enough PDMS was added that there is a layer of PDMS 827 disposed on a major surface 829 of the coating 820 opposite the silicon water 860.

In certain cases, in which the third material extends beyond an exterior surface of the coating (e.g., as shown in FIG. 8), it may be useful to etch the third material to remove at least some of the third material that extends beyond the exterior surface of the coating. Referring to FIG. 9, an SEM image is provided of a cross-section of a portion of a coating 920 that includes a three-dimensional porous matrix of silica nanoparticles 925 that was filled with a third material (i.e., polydimethylsiloxane (PDMS)), as described in detail below in Example 29. Enough PDMS was added that a layer 927 of the PDMS extends above the coating 920.

In certain embodiments, a portion of the third material is removed by reactive ion etching. Reactive ion etching (RIE) is a directional etching process utilizing ion bombardment to remove material. RIE systems are used to remove organic or inorganic material by etching surfaces orthogonal to the direction of the ion bombardment. The most notable difference between reactive ion etching and isotropic plasma etching is the etch direction Reactive ion etching is characterized by a ratio of the vertical etch rate to the lateral etch rate which is greater than 1. Systems for reactive ion etching are built around a durable vacuum chamber. Before beginning the etching process, the chamber is evacuated to a base pressure lower than 1 Torr, 100 milliTor (mTorr), 20 mTorr. 10 mTorr, or 1 mTorr. An electrode holds the materials to be treated and is electrically isolated from the vacuum chamber. The electrode may be a rotatable electrode in a cylindrical shape. A counter electrode is also provided within the chamber and may be comprised of the vacuum reactor walls. Gas comprising an etchant enters the chamber through a control valve. The process pressure is maintained by continuously evacuating chamber gases through a vacuum pump. The type of gas used varies depending on the etch process. Carbon tetrafluoride (CF), sulfur hexafluoride (SF₆), octafluoropropane (C₃F₈), fluoroform (CHF₃), boron trichloride (BCl₃), hydrogen bromide (HBr), chlorine, argon, and oxygen are commonly used for etching. RF power is applied to the electrode to generate a plasma Samples can be conveyed on the electrode through plasma for a controlled time period to achieve a specified etch depth. Reactive ion etching is known in the art and further described in U.S. Pat. No. 8,460,568 (David et al.); incorporated herein by reference.

Referring again to FIG. 9, in this case, the PDMS has been etched using reactive ion etching (as described in Example 29) and a portion of the PDMS reacted with the etch plasma to generate a layer 929 of SiO₂ on the remaining layer of PDMS 927. More generally, etching of the third material often forms an inorganic layer on an etched surface of the third material. Stated another way, certain articles have had a coating etched such that reaction of the third material with the etching environment (e.g., a plasma), generates a layer of an inorganic material on an exterior surface of the layer of the third material. The inorganic material may comprise silicon oxide, which will be located (e.g., disposed) on a portion of the third material as a result of the etching process.

Another option according to the present disclosure is to deposit a second coating on the coating opposite the substrate. For instance, in the embodiment shown in FIG. 3, the coating 320 further comprises a layer 330 of an inorganic material disposed on the coating 320 opposite the substrate 310. Exemplary inorganic materials include for instance and without limitation, silicon dioxide, silicon carbide, silicon oxycarbide, silicon nitride, silicon oxynitride, aluminum oxide, titanium oxide, zirconium oxide, stabilized zirconium oxide, silicon aluminum oxide, germanium, silicon doped boron or phosphorous, silicon aluminum, diamond, diamond-like carbon, diamond-like glass, amorphous silicon, hydrogenated amorphous silicon, or any combination thereof. In certain cases, these materials are deposited from the vapor phase using techniques such as sputtering, reactive sputtering, plasma-enhanced chemical vapor deposition (PECVD), atomic layer deposition (ALD), chemical vapor deposition (CVD), ion-assisted plasma chemical deposition, ion-beam deposition, cathodic arc deposition, etc. The inorganic material may be amorphous or at least partially crystalline. The term “diamond-like carbon” (DLC) refers to an amorphous film or coating comprising approximately 50 to 90 atomic percent carbon and approximately 10 to 50 atomic percent hydrogen, with a gram atom density of between approximately 0.20 and approximately 0.28 gram atoms per cubic centimeter, and composed of approximately 50% to approximately 90% tetrahedral bonds. The term “diamond-like glass” (DLG) refers to substantially or completely amorphous glass including carbon and silicon, and optionally including one or more additional components selected from the group including hydrogen, nitrogen, oxygen, fluorine, sulfur, titanium, and copper. Other elements may be present in certain embodiments. The amorphous diamond-like glass films may contain clustering of atoms to give it a short-range order but are essentially devoid of medium and long range ordering that lead to micro or macro crystallinity that can adversely scatter radiation having wavelengths of from 180 nanometers (nm) to 800 nm.

The structured substrate may be formed by any useful micro- or nano-replication technique. In some cases, the substrate has an area of at least 50 square centimeters. Such large areas, e.g., preparable by roll-to-roll technologies, are in contrast to silicon wafer-based processes, which typically are only up to 300 mm in diameter. Micro-replication and nano-replication refer to continuous thermal or photochemical processes for creating a structured surface layer using a cylindrical tool and a roll of polymeric support film with a thermoplastic (thermal) or UV-curable resin (photochemical) layer. For instance, one illustrative nano-replication technique is nanoimprint lithography (NIL). Nanoimprint lithography (NIL) is a high-throughput technique for patterning of polymer nanostructures at great precision and low cost. Unlike traditional lithographic approaches which achieve pattern definition by photon or electron beam exposure of a resist layer to modify the chemical and physical properties of the resist, NIL relies on the use of a stamp in a direct mechanical deformation of the resist material. The stamp is made from a master wafer and can be re-used in a rapid process to produce many copies of the original pattern. It is noted that NIL may also refer to the use of a replication step to put down a patterned layer that is used as a template or patterning layer, with subsequent etching steps resulting in the structure in an underlying layer.

The (e.g., flexible) substrate may be formed of a thermoplastic material. The substrate may be formed of any one or more of poly(methyl methacrylate), polycarbonate, polystyrene, polyester, polyamide, or polyolefins such as polypropylene, polyethylene, cyclic polyolefins, cyclic polyolefin copolymers, or polymethylpentene. The substrate may be formed of polymerizable compositions comprising acrylate or methacrylate components. The substrate may include a fluoropolymer, (meth)acrylate (co)polymer, or silica containing polymers. In some cases, the substrate includes a “land region”, which refers to the portion of a structured surface layer between its bottom surface and the plane defined by the bottom of the surface features. The height of that portion is the land region thickness. The land region can also be referred to as the residual layer or region. The land region of the substrate may have a uniform thickness, such as an average thickness in a range from about 5 micrometers to about 300 micrometers. The substrate may have a uniform thickness in a range from 10 micrometers to 250 micrometers, or from 25 micrometers to 125 micrometers.

Alternatively, in some cases, the features comprise an inorganic material. For instance, one suitable method for preparing a structured substrate having inorganic features is described in detail in U.S. Pat. No. 9,780,335 (Wolk et al.), incorporated herein by reference.

In some cases, the features may be referred to as microstructures. Typically, microstructures each have a smallest dimension (e.g., height, depth, or width) of 0.5 micrometers or greater, 1 micrometer, 2 micrometers, 3 micrometers, 4 micrometers, 5 micrometers, 6 micrometers, 7 micrometers, 8 micrometers, 9 micrometers, 10 micrometers, 12 micrometers, 15 micrometers, 17 micrometers, 20 micrometers, 25 micrometers, 30 micrometers, 35 micrometers, 40 micrometers, 45 micrometers, 50 micrometers, 60 micrometers, 70 micrometers, 80 micrometers, 90 micrometers, 100 micrometers, 150 micrometers, 200 micrometers, 250 micrometers, 300 micrometers, 350 micrometers, 400 micrometers, or 450 micrometers or greater, and 950 micrometers or less, 900 micrometers, 850 micrometers, 800 micrometers, 750 micrometers, 700 micrometers, 650 micrometers, 600 micrometers, 550 micrometers, 500 micrometers, 450 micrometers, 400 micrometers, 350 micrometers, 300 micrometers, 250 micrometers, 200 micrometers, 150 micrometers, 100 micrometers, 75 micrometers, 50 micrometers, or 25 micrometers or less.

In some cases, the features may be referred to as nanostructures. Typically, nanostructures each have a smallest dimension (e.g., height, depth, or width) of greater than 10 nanometers (nm), 20 nm, 30 nm, 40 nm, 50 nm, 75 nm, 100 nm, 125 nm, 150 nm, 175 nm, 200 nm, 225 nm, 250 nm, 300 nm, 325 nm, 350 nm, 375 nm, 400 nm, 450 nm, 500 nm, 550 nm, 600 nm, or 650 nanometers or greater, and less than 1 micrometer, 950 nm, 900 nm, 850 nm, 800 nm, 750 nm, 700 nm, 650 nm, 600 nm, 550 nm, or 500 nm or less.

In some cases, the smallest dimension of a feature may range from 500 nm to 2 micrometers or 100 nm to 10 micrometers, with a largest dimension of up to hundreds of micrometers. In certain embodiments, the features have an aspect ratio of height to width of at least 0.25:1, 0.5:1, 0.75:1, 1:1, 1.5:1, 2:1, 2.5:1, 3:1, 3.5:1, 4:1, 4.5:1, or at least 5:1. By “height” is meant the length of the feature that extends from the base of the major surface and by “width” is meant the shortest length of the feature orthogonal to the height. The features may comprise shapes including, but are not limited to, rectangular, triangular and trapezoidal prisms; fins, cylindrical and truncated-cone shaped pillars, etc. The features may be placed with regular or randomized pitch, orientation, and shapes, dependent on application-functionality and determined article design. The pitch is the distance between adjacent features. In some cases, the features have a pitch that is less than half of a predetermined wavelength of light.

Metamaterials are synthetic composite materials having nano-scale or micro-scale features on at least one surface. When the features are selected to have at least one dimension less than the wavelength of light impinging on the surface, the metamaterials may exhibit properties not readily obtainable using conventional materials and techniques. Metamaterials may have simple surface structures such as a single or small number of patterned layers or more complex surface structures such as stacked patterned layers, often in registration to each other, such that the individual features interact electromagnetically with impinging radiation according to their design. Metamaterials with a single or small number of patterned layers are called metasurfaces. Metasurfaces having nano-scale surface features, for instance, have recently found applications in optics, bio-sensing, semiconductors, and other electronic devices.

Metasurfaces have been formed on rigid surfaces using e-beam lithography and atomic layer deposition, for example. These materials have been formed on substrates having a limited surface area. These materials have been formed on wafer substrates having a diameter of 300 mm or less. More recently, optical metasurface polymeric films have been developed. Such optical metasurface polymeric films may be formed on flexible substrates, which may be large format substrates having a lateral dimension greater than 300 mm, for example. These optical metasurface polymeric films may be formed utilizing roll-to-roll processing with high fidelity.

For instance, as described in detail in PCT Publication No. WO 2021/220089 (Wolk et al.), incorporated herein by reference, an optical metasurface film may include a flexible polymeric film having a first major surface, a patterned polymer layer having a first surface proximate to the first major surface of the flexible polymeric film and having a second nanostructured surface opposite the first surface, and a refractive index contrast layer including a refractive index contrast material adjacent to the nanostructured surface of the patterned polymer layer forming a nanostructured bilayer with a nanostructured interface. The nanostructured bilayer comprises a plurality of nanostructures disposed on the flexible polymeric film. The nanostructured bilayer acts locally on an amplitude, phase, or polarization of light, or a combination thereof and imparts a light phase shift that varies as a function of position of the nanostructured bilayer on the flexible polymeric film. The light phase shift of the nanostructured bilayer defines a predetermined operative phase profile of the optical metasurface film. Alternatively, the structures may be microscale instead of nanoscale.

In some embodiments of articles according to the present disclosure, the coating is a refractive index contrast layer comprising a refractive index contrast material adjacent to the structured major surface of the substrate forming a structured bilayer with a structured interface, wherein the structured bilayer acts locally on an amplitude, phase, or polarization of light, or a combination thereof and imparts a light phase shift that varies as a function of position of the structured bilayer on the substrate, and the light phase shift of the structured bilayer defines a predetermined operative phase profile. As used herein, “structured bilayer” refers to a combination of the structured substrate and the coating.

Advantageously, in some embodiments, article(s) according to the present disclosure exhibit optical metasurface properties within a wavelength range of at least one of 400 nm to 1000 nm, 700 nm to 2500 nm or 1300 nm to 6000 nm. Optical metasurface properties in such wavelength ranges may be suitable for applications for thermal imaging, fingerprint sensing, and/or wireless communication. Additionally, an article optionally exhibits a transmission of at least 80% of light in the wavelength range. Transmission can be measured as described in ASTM E903-12 “Standard Test Method for Solar Absorptance, Reflectance, and Transmittance of Materials Using Integrating Spheres”.

### Structured Substrates

Many different structured substrates could be useful for articles according to the present disclosure. This section describes details of just a few suitable structured substrates that could optionally be employed.

### Stem Web Structure

FIG. 5 shows a structured substrate 510 having a stem web structure. In such embodiments, the structured substrate 510 comprises an array of upstanding stems 516 extending across the first surface 512 of the structured substrate 510. The structures 516 are generally upstanding stems of a variety of shapes. By “generally upstanding” it is meant that the stems protrude (e.g., in a planar direction) away from the first surface 512. The stems 516 may protrude upward from the surface 512 at generally normal angles, or the stems 516 may protrude at angles away from the surface 512. The stems may also be of an irregular shape such that they may not protrude at any one uniform angle.

The structured substrate 510 includes a backing layer 511 having a first surface 512 with an array of generally upstanding stems 516. The stems 516 may be arranged in a regular or an irregular array. Various patterns of stems may be used, such as hexagonal, diagonal, sinusoidal, etc. The stems 516 may be constructed at least in part of an elastomeric material. In some cases, the entire exterior surface of the stems 516 are an elastomeric material. In the embodiment of FIG. 5, the backing layer 511 is integrally formed with the stems 516. The combination of the backing layer 511 and the stems 516 is sometimes referred to as a stem web. Although the illustrated embodiments show the stems 516 as being generally cylindrical, the sides of the stems 516 typically have a slight taper 519 to facilitate removal from a mold. As shown, the taper 519 is inward from the base 513 to the tip 515 of the stem 516. It is expressly contemplated that the stem may be constructed having a taper outward from the base to the tip of the stem. A variety of non-cylindrical shapes can also be utilized, such as truncated cones or pyramids, rectangles, hemispheres, squares, hexagon, octagon, gum drops, and the like.

The backing layer 511, from which the stems 516 directly extend, is typically about 0.05 millimeters to about 0.5 millimeters (0.002 inches to 0.02 inches) thick. Additional backing layer(s) (not shown) are optionally to reinforce the backing layer 511 and form a multilayer base or backing construction. As used herein, “backing” or “base” layer will be used to refer to the collective backing or base construction. Such a construction may be single or multi-layered (such as shown in FIG. 1) having one or more layers that support the generally upstanding stems 516, although typically at most one of these layers 511 will be integrally formed with the stems 516.

The stems typically have a height 585 in the range of about 0.2 mm to about 3 mm, preferably about 0.2 mm to about 1.5 mm. The separation or gap 518 between adjacent stems 516 is generally in the range of about 0.25 mm and about 2.5 mm and more typically in the range of about 0.4 mm to about 1.0 mm. This separation gap creates a percent of free volume that is a volume within the stem web that is not occupied by the stems. The percent of free volume is typically from 60 to 98% of the stem web and more typically from 85 to 95%. The stems 516 have a maximum cross sectional dimension 517 of about 0.076 mm to about 0.76 mm. The stems 516 are arranged on the backing in a density of at least 15.5 per centimeter squared (100 per square inch), and more typically at least 50 per centimeter squared. The stem density is generally at most about 1500 per centimeter squared, more typically at most about 500 per centimeter squared. The stems have an aspect ratio of at least 1.25, and preferably at least 1.5, and most preferably at least 2.0. Aspect ratio refers to the ratio of stem height to the maximum cross sectional dimension. For stems with a circular cross section, the maximum cross sectional dimension is the stem diameter.

Suitable elastomeric stem materials include classes of elastomers such as anionic triblock copolymers, polyolefin-based thermoplastic elastomers, thermoplastic elastomers based on halogen-containing polyolefins, thermoplastic elastomers based on dynamically vulcanized elastomer-thermoplastic blends, thermoplastic polyether ester or polyester based elastomers, thermoplastic elastomers based on polyamides or polyimides, ionomeric thermoplastic elastomers, hydrogenated block copolymers in thermoplastic elastomer interpenetrating polymer networks, thermoplastic elastomers by carbocationic polymerization, polymer blends containing styrene/hydrogenated butadiene block copolymers, and polyacrylate-based thermoplastic elastomers. Some specific examples of elastomers are natural rubber, butyl rubber, EPDM rubber, silicone rubber such as polydimethyl siloxane, polyisoprene, polybutadiene, polyurethane, ethylene/propylene/diene terpolymer elastomers, chloroprene rubber, styrene-butadiene copolymers (random or block), styrene-isoprene copolymers (random or block), acrylonitrile-butadiene copolymers, mixtures thereof and copolymers thereof. The block copolymers may be linear, radial or star configurations and may be diblock (AB) or triblock (ABA) copolymers or mixtures thereof. Blends of these elastomers with each other or with modifying non-elastomers are also contemplated. Commercially available elastomers include block polymers (e.g., polystyrene materials with elastomeric segments), available from KRATON Polymers Company of Houston, Texas, under the designation KRATON™.

The elastomeric resin materials, such as those described above, may also have added to them any of a number of customary additives, including, for example, plasticizers, tackifiers, fillers, antioxidants, UV absorbers, hindered amine light stabilizers (HALS), dyes or pigments, opacifying agents and the like.

Suitable backing layer materials include thermoplastic polyurethanes, polyvinyl chlorides, polyamides, polyimides, polyolefins (e.g., polyethylene and polypropylene), polyesters (e.g., polyethylene terephthalate), polystyrenes, nylons, acetals, block polymers (e.g., polystyrene materials with elastomeric segments, available from KRATON Polymers Company of Houston, Texas, under the designation KRATON™, polycarbonates, thermoplastic elastomers (e.g., polyolefin, polyester or nylon types) and copolymers and blends thereof. In some cases, the entire stem web is formed of one or more thermoplastic materials, such as those listed above. The thermoplastic material may also contain additives, including but not limited to fillers, fibers, antistatic agents, lubricants, wetting agents, foaming agents, surfactants, pigments, dyes, coupling agents, plasticizers, suspending agents, hydrophilic/hydrophobic additives, adhesives, and the like.

Further details regarding structured substrates having such stem webs and how to form them are described in WO 2009/020811 (Tuman et al), incorporated herein by reference.

### Projection Array Structure

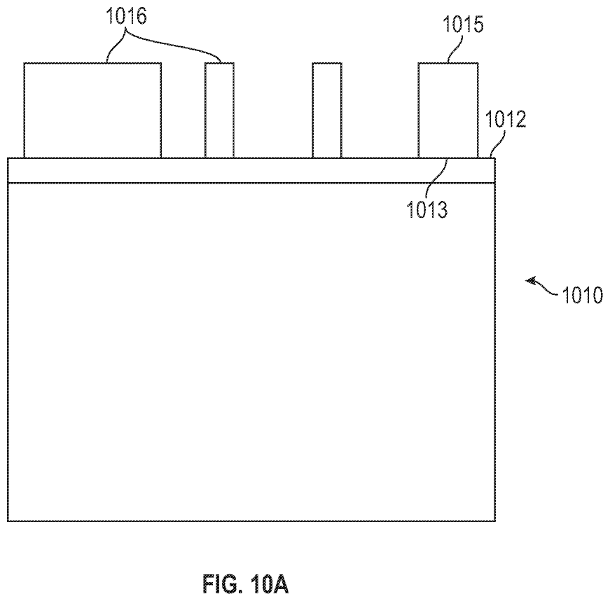

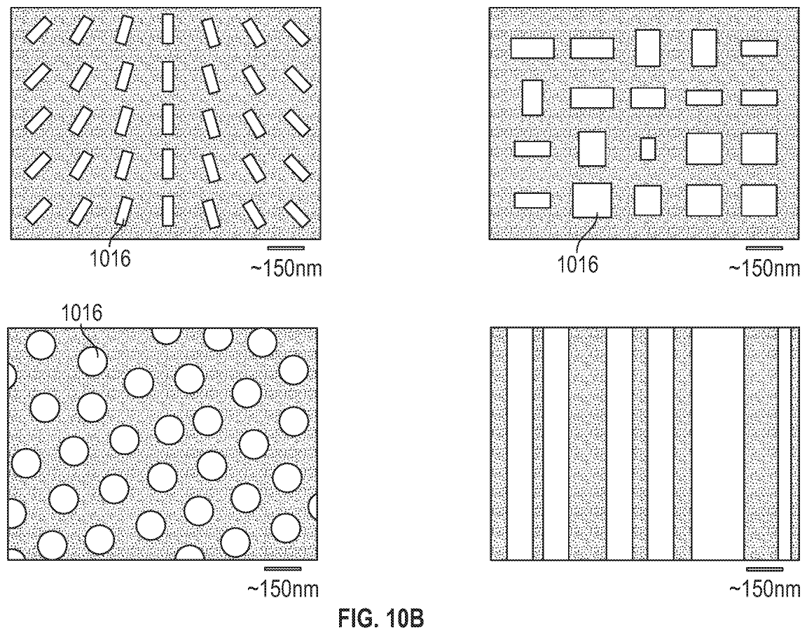

FIG. 10A shows an embodied structured substrate 1010 having a projection array structure, which can be coated to make an article according to the present disclosure. More particularly, FIG. 10A is a schematic cross-sectional view of a structured substrate 1010 that has a two-dimensional (x- and y-axes) array of projections 1016 arranged across a first surface 1012. Each of the projections 1016 comprises a base 1013, a top 1015, and one or more sides connecting the top to the base. Optionally, each of the projections 1016 is a spaced-apart post. For instance, FIG. 10B is a top plan view of four representative engineered patterned regions for a two-dimensional array of projections, including spaced-apart posts 1016 present in all but the lower right image. Some structured surfaces may comprise projections with a range of aspect ratio values, such as an array of projections with constant height and variable width. In such cases, the surface is usually characterized by the largest aspect ratio value. Often, a projection array structure is a nanostructure array, having feature sizes as described above with respect to the dimensions of nanostructures.

Further details regarding structured substrates having such projection arrays and how to form them are described in WO 2020/097319 (Wolk et al.), incorporated herein by reference.

### Cavity Array Structure

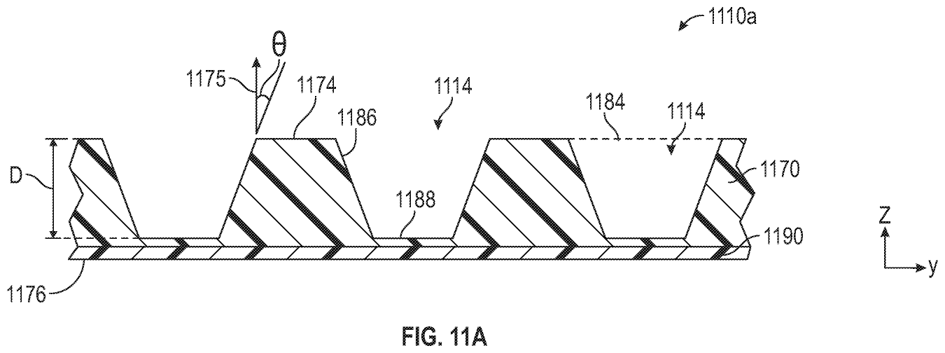

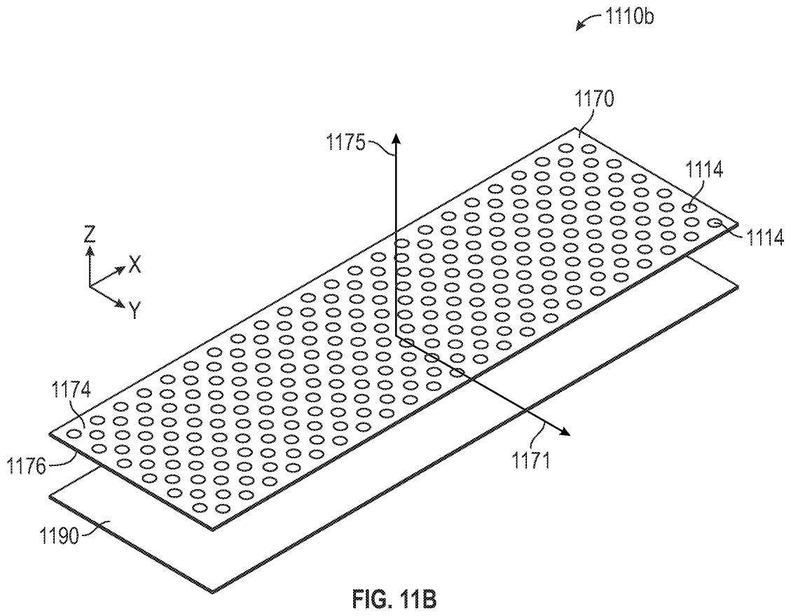

FIG. 11A shows an embodied structured substrate 1110a having a cavity array structure, which can be coated to make a coated article according to the present disclosure. A “cavity array” is an array of cavities having a density of discrete cavities of at least about 100/cm², and preferably at least about 10/mm². The cavities have a three-dimensional structure with dimensions, such as openings with, e.g., diameters in the range of between about 5-250 micrometers, and depths in the range between about 10 nanometers to 250 micrometers. The array can be any regular array such as a close-packed array or a rectangular array, or the cavities can be randomly distributed. More particularly, FIG. 11A is a schematic cross-sectional view of a structured substrate 1110a having a plurality of cavities 1114 extending between a first major surface 1174 and a second major surface 1176. The structured substrate 1110a comprises a structured layer 1170 with first 1174 and second 1176 major surfaces, in which the structures comprise a plurality of cavities 1114 extending between the first 1174 and second 1176 major surfaces. Each cavity comprises a first opening 1184, a second opening 1188 and at least one side wall 1186 extending between the first opening 1184 and the second opening 1188. Each of the side wall(s) 1186 forms a side wall angle θ with a line 1175 perpendicular to the first major surface 1174 of the structured layer 1170. Each of the cavities 1114 further includes a depth “D” which is the perpendicular distance between first aperture 1184 and second aperture 1188. Optionally, the structured film 1110a further includes a backing substrate 1190.

FIG. 11B is generalized schematic top perspective exploded view of a structured substrate 1110b having a plurality of cavities 1114 extending between two major surfaces. The structured substrate 1110b includes a structured layer 1170 with a first major surface 1174 and an opposing second major surface 1176. The first major surface 1174 includes an array of discrete cavities 1114. In one particular embodiment, each of the cavities 1114 includes a cross-section parallel to the first major surface 1174 that can be circular shaped, oval shaped, or polygon shaped. The cross-section optionally decreases in size in the direction from the first major surface 1174 to the second major surface 1176. This embodiment of a structured substrate 1110b further includes a (e.g., flexible) backing substrate 1190 coupled to the second major surface 1176 of the structured layer 1170. A set of coordinate axes is shown to illustrate that the cavities 1114 can be optically isolated such that light is not substantially transmitted within the plane formed by the x- and y-axes. However, light can be substantially transmitted from the cavities 1114 in a direction 1175 that is predominantly oriented toward the z-axis (that is, in the perpendicular direction from the structured film 1110b).

Further details regarding structured films having such cavity arrays and how to form them are described in U.S. Pat. No. 9,329,311 (Halverson et al.), incorporated herein by reference.

### EXEMPLARY EMBODIMENTS

In a first embodiment, the present disclosure provides an article. The article comprises a substrate comprising a structured major surface comprising features, wherein the structured major surface comprises protruding features, recessed features, or a combination thereof. The article also comprises a coating disposed on at least a portion of the features, the coating comprising a first material and a second material. The first material comprises a first binding group and the second material comprises a second binding group, and the first binding group and the second binding group have complementary interactions.

In a second embodiment, the present disclosure provides an article according to the first embodiment, wherein the features have a pitch that is less than half of a predetermined wavelength of light.

In a third embodiment, the present disclosure provides an article according to the first embodiment or the second embodiment, wherein the coating is a refractive index contrast layer comprising a refractive index contrast material adjacent to the structured major surface of the substrate forming a structured bilayer with a structured interface, wherein the structured bilayer acts locally on an amplitude, phase, or polarization of light, or a combination thereof and imparts a light phase shift that varies as a function of position of the structured bilayer on the substrate, and the light phase shift of the structured bilayer defines a predetermined operative phase profile.

In a fourth embodiment, the present disclosure provides an article according to any of the first through third embodiments, wherein the coating comprises a three-dimensional porous matrix, wherein the first material comprises nanoparticles.

In a fifth embodiment, the present disclosure provides an article according to the fourth embodiment, wherein the second material comprises a polyelectrolyte.

In a sixth embodiment, the present disclosure provides an article according to the fourth embodiment, wherein the second material comprises nanoparticles.

In a seventh embodiment, the present disclosure provides an article according to any of the fourth through sixth embodiments, wherein the nanoparticles comprise silicon dioxide.

In an eighth embodiment, the present disclosure provides an article according to any of the fourth through seventh embodiments, wherein the coating comprises a third material disposed in at least a portion of a plurality of pores of the porous matrix.

In a ninth embodiment, the present disclosure provides an article according to the eighth embodiment, wherein the third material comprises a silicon-containing material.

In a tenth embodiment, the present disclosure provides an article according to the ninth embodiment, wherein the third material comprises at least one of polydimethylsiloxane, a polysilsesquioxane, a polysiloxane, a silicone, a silicone acrylate, a silicate, a polycarbosilane, a polysilazane, or a siloxane-organic copolymer.

In an eleventh embodiment, the present disclosure provides an article according to the ninth embodiment or the tenth embodiment, further comprising silicon oxide disposed on a portion of the third material.

In a twelfth embodiment, the present disclosure provides an article according to any of the first through seventh embodiments, wherein the coating consists essentially of a three-dimensional porous matrix.

In a thirteenth embodiment, the present disclosure provides an article according to any of the first through twelfth embodiments, wherein the features comprise a top surface opposite the substrate and wherein the top surface of at least a portion of the features lacks the coating disposed thereon.

In a fourteenth embodiment, the present disclosure provides an article according to any of the first through twelfth embodiments, further comprising a layer of an inorganic material disposed on the coating opposite the substrate.

In a fifteenth embodiment, the present disclosure provides an article according to any of the first through fourteenth embodiments, wherein the coating and the features have different refractive indices from each other.

In a sixteenth embodiment, the present disclosure provides an article according to any of the first through fifteenth embodiments, wherein a difference in refractive index of the coating from the refractive index of the features (e.g., ΔRI) is at least 0.75.

In a seventeenth embodiment, the present disclosure provides an article according to any of the first through sixteenth embodiments, wherein the features have an aspect ratio of height to width of at least 0.75:1.

In an eighteenth embodiment, the present disclosure provides an article according to any of the first through seventeenth embodiments, wherein the substrate has an area of at least 50 square centimeters.

In a nineteenth embodiment, the present disclosure provides an article according to any of the first through eighteenth embodiments, wherein the structured major surface comprises a plurality of protruding features each comprising a base extending from the major surface and a top distal to the major surface, wherein a diameter at the base is equal to or greater than a dimeter at the top, and wherein a plurality of coated features each has a diameter at a top of the protruding feature that is greater than a diameter of a base.

In a twentieth embodiment, the present disclosure provides an article according to any of the first through eighteenth embodiments, wherein the coating has a major surface, opposite the substrate, that is substantially planarized.

In a twenty-first embodiment, the present disclosure provides an article according to any of the first through twentieth embodiments, wherein the features comprise an inorganic material.

In a twenty-second embodiment, the present disclosure provides an article according to any of the first through twenty-first embodiments, wherein the coating exhibits a refractive index of 1.25 to 1.45.

In a twenty-third embodiment, the present disclosure provides an article according to any of the first through twenty-second embodiments, exhibiting a transmission of at least 80% of light in a wavelength range of 1000 nanometers (nm) to 2000 nm.

In a twenty-fourth embodiment, the present disclosure provides an article according to any of the first through twenty-third embodiments, exhibiting optical metasurface properties within a wavelength range of at least one of 700 nm to 2500 nm or 1300 nm to 6000 nm.

In a twenty-fifth embodiment, the present disclosure provides a method of making an article. The method comprises obtaining a substrate comprising a structured major surface comprising features, wherein the structured major surface comprises protruding features, recessed features, or a combination thereof. The method further comprises disposing onto the structured major surface a plurality of layers deposited by layer-by-layer self-assembly, thereby forming a coating disposed on at least a portion of the features. The coating comprises a first material and a second material. The first material comprises a first binding group and the second material comprises a second binding group, and the first binding group and the second binding group have complementary interactions.

In a twenty-sixth embodiment, the present disclosure provides a method of making an article according to the twenty-fifth embodiment, further comprising depositing a second coating on the coating opposite the substrate.

In a twenty-seventh embodiment, the present disclosure provides a method of making an article according to the twenty-sixth embodiment, wherein the depositing is performed using vapor deposition.

In a twenty-eighth embodiment, the present disclosure provides a method of making an article according to any of the twenty-fifth through twenty-sixth embodiments, wherein the coating comprises a three-dimensional porous matrix, and wherein the method further comprises depositing a third material into a plurality of pores of the porous matrix.

In a twenty-ninth embodiment, the present disclosure provides a method of making an article according to the twenty-eighth embodiment, wherein the third material is deposited by applying a solution of the third material onto the coating.

In a thirtieth embodiment, the present disclosure provides a method of making an article according to the twenty-eighth embodiment or the twenty-ninth embodiment, further comprising crosslinking the third material.

In a thirty-first embodiment, the present disclosure provides a method of making an article according to any of the twenty-eighth through thirtieth embodiments, wherein the third material comprises a silicon-containing material.

In a thirty-second embodiment, the present disclosure provides a method of making an article according to any of the twenty-eighth through thirty-first embodiments, wherein the third material extends beyond an exterior surface of the coating and the method further comprises etching the third material to remove at least some of the third material that extends beyond the exterior surface of the coating.

In a thirty-third embodiment, the present disclosure provides a method of making an article according to the thirty-second embodiment, wherein the etching of the third material forms an inorganic layer on an etched surface of the third material.

In a thirty-fourth embodiment, the present disclosure provides a method of making an article according to any of the twenty-fifth through thirty-third embodiments, wherein the article is according to any of the first through twenty-fourth embodiments.

### EXAMPLES

Unless otherwise noted or apparent from the context, all parts, percentages, ratios, etc. in the Examples are by weight. Table 1 (below) lists materials used in the examples and their sources.

TABLE 1
Materials List

| DESIGNATION | DESCRIPTION | SOURCE |
|---|---|---|
| SR351 | Trimethylopropane triacrylate | Sartomer Americas, Exton, PA |
| SR238 | 1,6-Hexanediol diacrylate | Sartomer Americas, Exton, PA |
| PHOTOMER 6210 | Urethane acrylate oligomer | IGM Resins, Charlotte, NC |
| IRGACURE TPO | Diphenyl(2,4,6- | BASF, Florham Park, NJ |
| | trimethylbenzoyl)phosphine oxide | |
| Silicon wafer | 100 mm Silicon wafers, N-type doped | University Wafer, Boston, MA |
| | with P, <100> Res 0-100, 500 um thick, | |
| | SSP, Test-Grade | |
| NALCO 1056 | Colloidal dispersion of 20 nm-diameter | Nalco Water, Naperville, IL |
| | alumina-coated silica nanoparticles in | |
| | water at 30% solids concentration | |
| NALCO 2329 | Colloidal dispersion of 75 nm-diameter | Nalco Water, Naperville, IL |
| | silica nanoparticles in water at 40% | |
| | solids concentration | |
| SYLGARD 184 | PDMS Silicone Elastomer Kit | Dow Chemical Co., Midland, MI |
| HMDSO | Hexamethyldisiloxane | Alfa Aesar, Haverhill, MA |
| O₂ | Oxygen (OX UHP 300) | Airgas, St. Paul, MN |
| C₆F₁₄ | Perfluorohexane (3M PF-5060) | 3M, St. Paul, MN |
| NS-302 | Structured polymeric film having posts | Prepared according to PE-1 |
| | with a diameter of 1233 nm and a height | |
| | of 1250 nm | |
| NS-308 | Structured polymeric film having posts | Prepared according to PE-1 |
| | with a diameter of 1600 nm and a height | |
| | of 2800 nm | |
| NS-309 | Structured polymeric film having | Prepared according to PE-1 |
| | cavities with a diameter of 1233 nm and | |
| | a depth of 1250 nm | |
| BDEAS | Bis(diethylamino) silane | Air Liquide, Houston, TX |
| | CAS# 27804-64-4 | |
| N₂ | Nitrogen | Airgas, St. Paul, MN |
| N₂O | Nitrous oxide | Airgas, St. Paul, MN |

### Test Method

### Spectroscopic Ellipsometry

Spectroscopic ellipsometry (SE) measurements were collected with a dual-rotating compensator ellipsometer (RC2-X from J.A. Woollam Co.) at 790 wavelengths between 200-1000 nim. Measurements were collected in reflection at angles of 65, 70, 75 and 80°, unless otherwise noted. The resulting data was analyzed or modeled in CompleteEase software available from J.A. Woollam Co. Reference material files in CompleteEase were used for the Si wafer (Si-JAW) substrate and the native oxide layer (NTVE_JAW), which was fixed to 10 angstroms based on previous measurements. The deposited coatings were modeled using Cauchy dispersion (treated as a single composite film) with an optional overlayer of PDMS, whose optical constants were modeled with Cauchy dispersion and fixed based on previous single-layer measurements. The modeled wavelength region was restricted to 400-1000 nm, unless otherwise noted, to avoid regions of strong absorption. Also included in the model was thickness non-uniformity (about 1-2%) and instrument bandwidth, as this was needed to account for observed depolarization.

### Scanning Electron Microscopy (SEM) Imaging

Samples were mounted on aluminum examination stubs and coated with AuPd by DC sputtering in a Denton Vacuum Desk IV coater to ensure conductivity. Examinations were performed in a Hitachi S4700 Field Emission Scanning Electron Microscope. SEM instrument conditions included accelerating voltage of 3.0 kV and 6.6-8.4 mm working distance (wd). Images were taken at magnifications ranging from 10,000× to 100,000×.

### Stylus Profilometry

The coating thickness was measured with a Dektak XT stylus profilometer (Bruker Nano Inc., Tucson, Arizona) after scratching the LbL coating (on a rigid glass or silicon wafer substrate) with a razor blade.

### Attenuated Total Reflectance—Infrared Spectroscopy (ATR-IR)

The presence of hydrocarbons was monitored via attenuated total reflectance-infrared (ATR-IR) spectroscopy using a Nicolet™ iS™ 10 FTIR spectrometer (Thermo Fisher Scientific, Waltham, MA) with a Smart iTX accessory equipped with diamond detector.

### PREPARATIVE EXAMPLES

### Preparative Example 1

### Preparation of Structured Film

Resin A was prepared by combining and mixing PHOTOMER 6210, SR351, SR238 and IRGACURE TPO in respective weight ratios of 60/20/20/0.5. After all components were added the resin composition was blended by warming to approximately 50° C. and mixing for 12 hours on a roller mixer. Mixture should appear homogeneous.

A structured film was prepared by die coating Resin A onto a 125 micrometer thick polyester film (available from Dupont as ST505). The coated side of the film was pressed against a structured nickel surface that had one of 3 different structured patterns that was attached to a steel roller controlled at 60° C. using a rubber covered roller at a speed of 15.2 meters per minute. The coating thickness of Resin A on the film was sufficient to fully wet the nickel surface and form a rolling bead of resin as the coated film was pressed against the nanostructured nickel surface. The film was exposed to radiation from two UV lamp systems (obtained under the trade designation “F600” from Fusion UV Systems, Gaithersburg, MD) fitted with D bulbs both operating at 142 Watts per centimeter (W/cm), while in contact with the nanostructured mold surface. The resulting structured film was peeled from the structured mold surface and then the structured surface of the film was exposed to radiation from a UV lamp system (obtained under the trade designation “F600” from Fusion UV Systems) fitted with a D bulb operating at 142 W/cm. Use of the three different structured patterns resulted in lower aspect ratio features with diameters of 1233 nm and heights of 1250 nm (in the form of posts on NS-302 and holes on NS-309) and a higher aspect ratio post pattern (NS-308) with a diameter of 1600 nm and height of 2800 m.

### General Method for Fabricating Layer-by-Layer SiO₂ Coatings

The layer-by-layer constructions were prepared on silicon wafer, PET film, and nanopatterned posts and wells. For the coatings on silicon wafer, the substrates were initially rinsed with isopropyl alcohol, dried with nitrogen, and plasma cleaned for 5 minutes. The silicon wafer was then mounted on the sample holder of a robotic dip coater like the system reported in Gamboa, et al, Review of Scientific Instruments 51, 036103 (2010). The automatic dip coater can be programmed to alternately immerse the substrate in the cationic and anionic nanoparticle solutions. The coater was equipped with spray nozzles to rinse the substrates with deionized water immediately after immersion in a coating solution and separate nozzles with compressed air to dry the substrates. The total dwell time for each immersion was 24 seconds. To fabricate the LbL silica coatings, the substrate was immersed in an aqueous suspension of 1% solids NALCO 1056 at pH 3, washed with water, and dried with nitrogen. Afterwards, it was then immersed in an aqueous suspension of 1% solids NALCO 2329 (negatively charged silica) at pH 3, washed with water, and dried with nitrogen. This sequence, which corresponds to 1 bilayer, was repeated until the desired number of bilayers were deposited. The resulting LbL coating is denoted by (Cation/Anion)ₙ, where n is the number of bilayers.

To prepare a sample on PET or one of the structured substrates made according to PE-1, a sheet of polymer film was cut into a 4″×4″ (10.2 centimeters (cm)×10.2 cm) piece and adhered at the edges on a 4″×4.75″ (10.2 cm×12.0 cm) glass plate with epoxy (Scotch-Weld epoxy adhesive obtained as DP100 CLEAR, 3M Company, St. Paul, MN, USA). The substrate was corona treated by hand using a BD-20AC Laboratory Corona Treater (Electro-Technic Products, Chicago, IL, USA). Then, the robotic dip coater was used to coat 1-35 bilayers of the LbL SiO₂ coating.

### General Method for Atomic Layer Deposition

SiO₂ coatings were deposited using a rotary spatial ALD system from Kurdex, Inc. (Sunnyvale, California). The chamber is divided into four zones:
a precursor zone where the precursor is chemisorbed on the surface of the substrate
a separation (purge) zone to isolate the precursor and plasma zone
a plasma zone to oxidize the precursor chemisorbed on the surface
a separation (purge) zone to isolate the precursor and plasma zone

The rotary substrate platen and top chamber wall were heated to 90° C. The substrate was fixed to the rotary plate and the chamber was pumped to a base pressure of less than 20 mTorr. Bis(diethylamino)silane (BDEAS) was used as the Si precursor source and was heated to 40° C. The precursor was continuously transported to the precursor zone through a gas manifold heated to 90° C. A mixture of nitrogen and nitrous oxide was introduced to the separation zone at flow rates of 1260 and 500 sccm, respectively. 500 W of DC power was applied to the plasma electrode using a 10 kW Pinnacle DC generator from Advanced Energy Industries (Fort Collins, CO). During deposition, the substrate platen was rotated, with each rotation comprising one ALD cycle, until the target number of cycles was reached.

### General Method for Plasma Treatment (Reactive Ion Etching)

The procedure for reactive ion etching was as follows: the samples were etched using a Plasma-Therm 3032 batch plasma reactor (obtained from Plasma-Therm LLC, St. Petersburg, FL). The instrument was configured for reactive ion etching with a 26″ (66.04 cm) lower powered electrode and central gas pumping. The chamber was pumped with a roots type blower (model EH1200 obtained from Edwards Engineering, Burgess Hill, UK)) backed by a dry mechanical pump (model iQDP80 obtained from Edwards Engineering). The RF power was delivered by a 3 kW, 13.56 MHz solid-state generator (RFPP model RF30S obtained from Advanced Energy Industries, Fort Collins, CO). The flow rates of the gases were controlled by MKS flow controllers (obtained from MKS Instruments, Andover, MA). Samples were fixed on the powered electrode of the plasma reactor. After pumping down to a base pressure of less than 5 mTorr, oxygen and perfluorohexane gas was introduced into the chamber (250 and 50 sccm, respectively). RF power (2000 W) was applied to the electrode for 60 seconds. Following completion of this step, a post-treatment was performed according to the same procedure with oxygen gas (250 sccm) for 30 seconds. During these steps, no active pressure control was used, resulting in a process pressure of about 62 mTorr during the oxygen and perfluorohexane etch step and 37 mTorr during the oxygen plasma post-treatment.

### EXAMPLES

### Examples 1-9

### Fabrication of All Silica Nanoparticle LbL Coating (LbL SiO₂)

Samples EX 1 to 5 composed of silicon wafers coated with increasing bilayers of LbL SiO₂ coatings were prepared using the General Method for Fabricating Layer-by-Layer SiO₂ Coatings. Table 2 details the coating conditions as well as the average profilometric thickness for each sample. The increasing thickness measurements up to 1.4 micrometers as a function of increasing bilayers demonstrated the successful layer-by-layer deposition of NALCO 1056 and NALCO 2329 due to the electrostatic interaction between the oppositely charged silica nanoparticles. Moving forward, coated samples with 35 bilayers of LbL SiO₂ coatings would be used since approximately 1.2 micrometer-thick coatings are required to completely fill the nanopatterns of the nanostructured substrates. ATR-IR spectra of these samples confirmed the absence of any methyl peaks.

TABLE 2
Coating conditions for EX 1-5.

| Sample | Substrate | Number of Bilayers | Average Thickness |
|---|---|---|---|
| EX 1 | Silicon Wafer | 10 | 235.2 ± 13.1 nm |
| EX 2 | Silicon Wafer | 30 | 1078.25 ± 22.5 nm |
| EX 3 | Silicon Wafer | 35 | 1219.85 ± 34.6 nm |
| EX 4 | Silicon Wafer | 40 | 1394.89 ± 47.8 nm |
| EX 5 | Silicon Wafer | 50 | 1414.06 ± 45.4 nm |

In addition to silicon wafers, non-patterned and nanopatterned polymeric films EX 6 to 9 (see Table 3 for conditions) were coated with LbL SiO₂ coatings. Based on SEM analysis, the LbL SiO₂ coatings conformally coated the nanoscale features of the nanopatterned films.

TABLE 3
Coating conditions for EX 6-9.

| Sample | Substrate | Number of Bilayers |
|---|---|---|
| EX 6 | PET | 35 |
| EX 7 | NS-302 | 35 |
| EX 8 | NS-308 | 35 |
| EX 9 | NS-309 | 35 |

### Examples 10-19

Backfilling the LbL SiO₂Coating with Atomic Layer Deposited SiO₂ (ALD SiO₂)

Based on the SEM images of the LbL SiO₂ coatings, the resulting morphology of the coatings composed only of silica nanoparticle coatings seemed to be falling apart upon fracture of the samples for cross-sectional SEM analysis and can potentially affect the mechanical properties of the coating. To improve the overall robustness of the coating, a thin layer of silica was subsequently deposited on the LbL SiO₂ coatings by atomic layer deposition as detailed in the General Method for Atomic Layer Deposition. EX 10-19 were prepared by initially depositing LbL SiO₂ coatings using the General Method for Fabricating Layer-by-Layer SiO₂ Coatings and then subsequent ALD of SiO₂ as listed in Table 4. Based on SEM images of the samples, the deposited ALD SiO₂ coating is concentrated on the outermost surface of the LbL SiO₂ coating instead of completely backfilling the porous structure throughout the depth of the LbL SiO₂ coating. Even though the ALD SiO₂ did not completely penetrate the porous morphology of the nanoparticle coating, covering the LbL SiO₂ coating with a subsequent layer of ALD SiO₂ is expected to lock in the nanoparticles into place and provide better mechanical properties for the overall coating.

TABLE 4
Coating conditions for EX 10-19.

| | | | Number of | Rotary Speed for ALD | ALD |
|---|---|---|---|---|---|
| Sample | Substrate | Initial LbL Coating | Bilayers | SiO₂ Deposition (rpm) | Cycles |
| EX 10 | PET | (Nalco 1056/Nalco 2329)₁₀ | 10 | 30 | 400 |
| EX 11 | NS-302 | (Nalco 1056/Nalco 2329)₃₅ | 35 | 5 | 500 |
| EX 12 | NS-302 | (Nalco 1056/Nalco 2329)₃₅ | 35 | 10 | 500 |
| EX 13 | NS-302 | (Nalco 1056/Nalco 2329)₃₅ | 35 | 20 | 500 |
| EX 14 | NS-308 | (Nalco 1056/Nalco 2329)₃₅ | 35 | 5 | 500 |
| EX 15 | NS-308 | (Nalco 1056/Nalco 2329)₃₅ | 35 | 10 | 500 |
| EX 16 | NS-308 | (Nalco 1056/Nalco 2329)₃₅ | 35 | 20 | 500 |
| EX 17 | NS-309 | (Nalco 1056/Nalco 2329)₃₅ | 35 | 5 | 500 |
| EX 18 | NS-309 | (Nalco 1056/Nalco 2329)₃₅ | 35 | 10 | 500 |
| EX 19 | NS-309 | (Nalco 1056/Nalco 2329)₃₅ | 35 | 20 | 500 |

### Examples 20-28

Backfilling the LbL SiO₂ Coating with PDMS

In addition to ALD backfilling, another strategy used for backfilling and holding the porous structure of the LbL SiO₂ coating together was subsequently coating the LbL coating with polydimethylsiloxane (PDMS) and thermally curing it. For examples EX 20 to 28, 35 bilayers of LbL SiO₂ coatings (i.e., (1056/2329)₃₅) were deposited on plasma cleaned silicon wafer using the General Method for Fabricating Layer-by-Layer SiO₂ Coatings. Afterwards, diluted PDMS solutions for spin coating were prepared by mixing the Dow SYLGARD 184 PDMS polymeric base (14 g) and the accompanying curing agent (2 g) in a speed mixer cup, in a ratio of PDMS base to crosslinker of 7:1. The mixture was speed mixed at 3000 rpm for at least 30 seconds. Then, corresponding amounts of the PDMS mixture was weighed into a 20 mL glass vial, diluted with hexamethyldisiloxane (HMDSO) to create solutions with PDMS concentrations between 1-20%, and homogenized in a vortex mixer. The diluted PDMS solutions were then spin coated onto the silicon wafers coated LbL SiO₂ coatings first at 500 rpm for 5 sec then 1500 for 30 sec to create examples EX 21 to 28. Table 5 lists the varying coating conditions.

TABLE 5

| | | | Thickness | | |
|---|---|---|---|---|---|
| | | Thickness of the | of excess | n | n |
| | PDMS | LbL SiO₂ w/ | PDMS | 510 | 1000 |
| Sample | Concentration | backfill (nm) | (nm) | nm | nm |
| EX 20 | — | 1535 | — | 1.27 | 1.27 |
| EX 21 | 1% | 1607 | — | 1.30 | 1.29 |
| EX 22 | 2.5% | 1604 | — | 1.34 | 1.33 |
| EX 23 | 5% | 1683 | — | 1.37 | 1.36 |
| EX 24 | 6% | 1022 | 134 | 1.43 | 1.42 |
| EX 25 | 7% | 1156 | 203 | 1.43 | 1.42 |
| EX 26 | 8% | 1178 | 288 | 1.43 | 1.42 |
| EX 27 | 10% | 1315 | 947 | 1.41 | 1.40 |
| EX 28 | 20% | 1338 | 2195 | 1.42 | 1.41 |

Spectroscopic ellipsometry and SEM imaging were used to characterize the level of backfilling of the LbL SiO₂ coating with PDMS and the refractive index (n) of each coating at wavelengths of 510 nm and 1000 nm. By modelling the spectroscopic ellipsometry results, the thickness of the LbL coating with or without the backfilling PDMS and the excess PDMS overlayer can be decoupled into separate layers, as shown in Table 5 above. For the LbL SiO₂ samples backfilled with PDMS solutions with less than or equal to 5% PDMS concentrations, the data were not consistent with a PDMS overlayer. Beyond 5% PDMS, the thickness of the PDMS overlayer continuously increased from 134 nm to 2.2 microns. On the other hand, the refractive index gradually increased with the PDMS concentration from 0% to 5% showing a stepwise backfilling of the porous structure with PDMS. Starting at 5% PDMS concentration, the refractive index of the composite coating plateaus at about 1.4, which is the average refractive index of PDMS. SEM imaging supports these observations from spectroscopic ellipsometry as the cross-sectional images of the coatings revealed that a PDMS overlayer starts to build up at PDMS concentrations higher than 5%.

### Example 29

### Reactive Ion Etching of PDMS-Backfilled LbL SiO₂

As described in the General Method for Plasma Treatment (Reactive Ion Etching), LbL SiO₂ coatings subsequently coated with PDMS begin to saturate available porosity and form an overlayer of PDMS above 5% PDMS concentration. Removing this overlayer may be advantageous to simplify the construction and reduce any absorption from excess PDMS and may be accomplished by etching in a C₆F₁₄ and O₂ plasma, or other fluorine-containing plasma. EX 29 was prepared using the General Method for Plasma Treatment (Reactive Ion Etching) using the conditions listed in Table 6 below.

TABLE 6

| | | O₂ | C₆F₁₄ | | | |
|---|---|---|---|---|---|---|
| | | Flow | Flow | | | Etch |
| | Input | Rate | Rate | Power | Pressure | Time |
| Sample | Substrate | (sccm) | (sccm) | (W) | (mTorr) | (sec) |
| EX 24 | Silicon | | | | | N/A |
| | Wafer | | | | | (control) |
| EX29_A | EX24 | 250 | 50 | 2000 | 62 | 60 |
| EX29 | EX29_A | 250 | 0 | 2000 | 37 | 30 |

Spectroscopic ellipsometry (SE) was used to characterize the etched samples. The thickness of the LBL SiO₂ with backfill and the thickness of excess PDMS, the refractive index (n) and the extinction coefficient (k) are reported in Table 7. The SE data is consistent with complete removal of the PDMS overlayer, and reduced thickness of the LbL SiO₂/PDMS layer, indicating a small amount of this composite layer was also etched during the treatment. The refractive index of the composite LbL SiO₂/PDMS layer after etching was not significantly different relative to measurement before etching. For future work, the etch time or etch process parameters (gas flows, power) could be adjusted to stop after removing substantially all of the PDMS overlayer without substantially etching into the LbL SiO₂/PDMS composite layer.

TABLE 7

| | Thickness of | Thickness | n | n |
|---|---|---|---|---|
| | LbL SiO₂ w/ | of PDMS | 510 | 1000 |
| Sample | backfill (nm) | overlayer (nm) | nm | nm |
| EX 24 | 1022 | 134 | 1.433 | 1.422 |
| EX29_A | N.M.* | N.M. | N.M. | N.M. |
| EX29 | 959 | 0 | 1.446 | 1.434 |

*N.M. means “not measured”. The sample was not removed from the plasma reactor between the two etching steps.

### Examples 30-34

### ATR-IR Characterization of the Hydrocarbons in the Coatings

The presence of the hydrocarbons in the coatings deposited onto silicon wafer was determined by monitoring the sharp C—H stretch peak centered at ~2962 cm⁻¹ using ATR-IR spectroscopy. No hydrocarbon peak was observed in EX 20, which is a silicon wafer sample coated with 35 bilayers of (Nalco 1056/Nalco 2329). The C—H peak was then detected upon backfilling with PDMS. The intensity increased accordingly with increasing PDMS concentration (EX 21, 22, 23, 27, and 2). A decrease in the intensity of the C—H peak was observed when LbL SiO₂ coating backfilled with 5% PDMS (EX 23) was exposed to oxygen reactive ion etching, which could have converted the PDMS in the outermost layer of the coating to SiO₂. On the other hand, the LbL SiO₂ coatings backfilled with ALD-deposited SiO₂ (EX 32-34) did not have any measurable hydrocarbon peaks.

TABLE 8

| | | | | Subsequent | |
|---|---|---|---|---|---|
| | | | Secondary | Reactive Ion | Absorbance of |
| Sample | Substrate | LbL Coating | Coating | Etching | C—H Peak |
| EX 20 | Silicon Wafer | (Nalco 1056/Nalco 2329)₃₅ | — | — | 0 |
| EX 21 | Silicon Wafer | (Nalco 1056/Nalco 2329)₃₅ | 1% PDMS | — | 0.0016 |
| EX 22 | Silicon Wafer | (Nalco 1056/Nalco 2329)₃₅ | 2.5% PDMS | — | 0.0024 |
| EX 23 | Silicon Wafer | (Nalco 1056/Nalco 2329)₃₅ | 5% PDMS | — | 0.0250 |
| EX 27 | Silicon Wafer | (Nalco 1056/Nalco 2329)₃₅ | 10% PDMS | — | 0.0412 |
| EX 28 | Silicon Wafer | (Nalco 1056/Nalco 2329)₃₅ | 20% PDMS | — | 0.0739 |
| EX 30 | Silicon Wafer | (Nalco 1056/Nalco 2329)₃₅ | 5% PDMS | 60 sec 2000 W | 0.0044 |
| | | | | 300 sccm O₂ | |
| EX 31 | Silicon Wafer | — | 20% PDMS | — | 0.0597 |
| EX 32 | Silicon Wafer | (Nalco 1056/Nalco 2329)₃₅ | 20 nm ALD | — | 0 |
| | | | SiO₂ | | |
| EX 33 | Silicon Wafer | (Nalco 1056/Nalco 2329)₃₅ | 50 nm ALD | — | 0 |
| | | | SiO₂ | | |
| EX 34 | Silicon Wafer | (Nalco 1056/Nalco 2329)₃₅ | 100 nm ALD | — | 0 |
| | | | SiO₂ | | |

All cited references, patents, and patent applications in the above application for letters patent are herein incorporated by reference in their entirety in a consistent manner. In the event of inconsistencies or contradictions between portions of the incorporated references and this application, the information in the preceding description shall control. The preceding description, given in order to enable one of ordinary skill in the art to practice the claimed disclosure, is not to be construed as limiting the scope of the disclosure, which is defined by the claims and all equivalents thereto.

1. An article comprising:
a substrate comprising a structured major surface comprising features, wherein the structured major surface comprises protruding features, recessed features, or a combination thereof, and
a coating disposed on at least a portion of the features, the coating comprising a first material and a second material, wherein the first material comprises a first binding group and the second material comprises a second binding group, and wherein the first binding group and the second binding group have complementary interactions.

2. The article of claim 1, wherein the features have a pitch that is less than half of a predetermined wavelength of light.

3. The article of claim 1, wherein the coating is a refractive index contrast layer comprising a refractive index contrast material adjacent to the structured major surface of the substrate forming a structured bilayer with a structured interface, wherein the structured bilayer acts locally on an amplitude, phase, or polarization of light, or a combination thereof and imparts a light phase shift that varies as a function of position of the structured bilayer on the substrate, and the light phase shift of the structured bilayer defines a predetermined operative phase profile.

4. The article of claim 1, wherein the coating comprises a three-dimensional porous matrix, wherein the first material comprises nanoparticles.

5. (canceled)

6. The article of claim 4, wherein the second material comprises nanoparticles.

7. The article of claim 4, wherein the nanoparticles comprise silicon dioxide.

8. The article of claim 4, wherein the coating comprises a third material disposed in at least a portion of a plurality of pores of the porous matrix.

9. The article of claim 8, wherein the third material comprises a silicon-containing material.

10. The article of claim 9, wherein the third material comprises at least one of polydimethylsiloxane, a polysilsesquioxane, a polysiloxane, a silicone, a silicone acrylate, a silicate, a polycarbosilane, a polysilazane, or a siloxane-organic copolymer.

11. The article of claim 1, wherein the features comprise a top surface opposite the substrate and wherein the top surface of at least a portion of the features lacks the coating disposed thereon.

12. The article of claim 1, further comprising a layer of an inorganic material disposed on the coating opposite the substrate.

13. The article of claim 1, wherein the coating and the features have different refractive indices from each other.

14. The article of claim 1, wherein a difference in refractive index of the coating from the refractive index of the features (ΔRI) is at least 0.75.

15. The article of claim 1, wherein the structured major surface comprises a plurality of protruding features each comprising a base extending from the major surface and a top distal to the major surface, wherein a diameter at the base is equal to or greater than a diameter at the top, and wherein a plurality of coated features each has a diameter at a top of the protruding feature that is greater than a diameter of a base.

16. The article of claim 1, exhibiting a transmission of at least 80% of light in a wavelength range of 1000 nanometers (nm) to 2000 nm.

17. The article of claim 1, exhibiting optical metasurface properties within a wavelength range of at least one of 700 nm to 2500 nm or 1300 nm to 6000 nm.

18. A method of making an article, the method comprising:
obtaining a substrate comprising a structured major surface comprising features, wherein the structured major surface comprises protruding features, recessed features, or a combination thereof, and
disposing onto the structured major surface a plurality of layers deposited by layer-by-layer self-assembly, thereby forming a coating disposed on at least a portion of the features, the coating comprising a first material and a second material, wherein the first material comprises a first binding group and the second material comprises a second binding group, and wherein the first binding group and the second binding group have complementary interactions.

19. The method of claim 18, further comprising depositing a second coating on the coating opposite the substrate, optionally wherein the depositing is performed using vapor deposition.

20. The method of claim 18, wherein the coating comprises a three-dimensional porous matrix, and wherein the method further comprises depositing a third material into a plurality of pores of the porous matrix, optionally wherein the third material is deposited by applying a solution of the third material onto the coating.

21. The method of claim 20, further comprising crosslinking the third material.

22. The method of claim 20, wherein the third material extends beyond an exterior surface of the coating and the method further comprises etching the third material to remove at least some of the third material that extends beyond the exterior surface of the coating.

23. The method of claim 22, wherein the etching of the third material forms an inorganic layer on an etched surface of the third material.

24. (canceled)
